(19) United States
(12) Patent Application Publication
(10) Pub. No.: US 2026/0215184 A1
(43) Pub. Date: Jul. 23, 2026

(54) SELECTIVE THIN-FILM ETCHING METHOD AND METHOD OF MANUFACTURING SEMICONDUCTOR DEVICE BY USING THE SAME

(71) Applicant: SAMSUNG ELECTRONICS CO., LTD., Suwon-si (KR)

(72) Inventors: Hyejeong JANG, Suwon-si (KR); Yuki YAMADA, Tokyo (JP); Yeonock HAN, Suwon-si (KR); Daisuke SATO, Tokyo (JP); Yuki OKA, Tokyo (JP); Kazuma MATSUI, Tokyo (JP); Wonwoong CHUNG, Suwon-si (KR); Younjoung CHO, Suwon-si (KR)

(73) Assignees: SAMSUNG ELECTRONICS CO., LTD., Suwon-si (KR); Resonac Corporation, Tokyo (JP)

(21) Appl. No.: 19/448,300

(22) Filed: Jan. 14, 2026

(30) Foreign Application Priority Data
Jan. 20, 2025 (KR) 10-2025-0008183

(51) Int. Cl. H10P 50/24; H01J 37/32; H10B 12/00; H10P 50/00

(52) U.S. Cl. CPC H10P 50/242; H01J 37/3244; H10B 12/03; H10B 12/05; H10B 12/30; H10P 50/691; H01J 2237/334

(57) ABSTRACT

A selective thin-film etching method includes forming a stacked structure on a substrate by alternately stacking a plurality of silicon germanium layers and a plurality of silicon layers, forming mask patterns, at least one of which is arranged at different intervals with respect to at least some adjacent mask patterns, on the stacked structure, performing first etching to expose an upper surface of a lowermost layer of the stacked structure and second etching to expose an upper surface of the substrate, and removing the mask patterns. In the first etching, the mask patterns are used as an etch mask, chlorine gas is used as a first etch gas, and first plasma is formed in a process chamber. In the second etching, the mask patterns are used as an etch mask, an interhalogen gas is used as a second etch gas, and second plasma is formed in the process chamber.

### CROSS-REFERENCE TO RELATED APPLICATION

This application is based on and claims priority under 35 U.S.C. § 119 to Korean Patent Application No. 10-2025-0008183, filed on Jan. 20, 2025, in the Korean Intellectual Property Office, the disclosure of which is incorporated by reference herein in its entirety.

### BACKGROUND

The inventive concept relates to a selective thin-film etching method and a method of manufacturing a semiconductor device by using the same, and more particularly, to a selective thin-film etching method using an etch gas with a high selectivity and a method of manufacturing a semiconductor device by using the same.

In a process of manufacturing a semiconductor device, an etching process is required to etch an etch target layer on a semiconductor substrate in a certain pattern. The etching process includes a dry etching process and a wet etching process, and a plasma etching process is a type of dry etching process. The plasma etching process may be used in a plasma etching apparatus so as to manufacture a semiconductor device.

The plasma etching apparatus may perform plasma etching on an etch target layer on a semiconductor substrate by using plasma within a process chamber. When plasma etching is performed on a semiconductor substrate within a process chamber by using a plasma etching apparatus, it is important to accurately etch an etch target layer on the semiconductor substrate.

### SUMMARY

The inventive concept provides a selective thin-film etching method, in which productivity and cost reduction may be improved by etching a desired thin-film in an accurate pattern on an exposed surface of a stacked structure, in which different materials are alternately stacked, by a plasma etching process using an etch gas with a high selectivity, and a method of manufacturing a semiconductor device by using the selective thin-film etching method.

The objectives of the inventive concept are not limited to those described above, and other objectives that are not described herein will be clearly understood from the following description by those of ordinary skill in the art.

According to an aspect of the inventive concept, there is provided a selective thin-film etching method including forming a stacked structure on a substrate by alternately stacking a plurality of silicon germanium layers and a plurality of silicon layers, forming mask patterns, at least one of which is arranged at different intervals with respect to at least some adjacent mask patterns, on the stacked structure, performing first etching in which the mask patterns are used as an etch mask, chlorine gas is used as a first etch gas, and first plasma is formed in a process chamber to expose an upper surface of a lowermost layer of the stacked structure, performing second etching in which the mask patterns are used as an etch mask, an interhalogen gas is used as a second etch gas, and second plasma is formed in the process chamber to expose an upper surface of the substrate, and removing the mask patterns.

According to another aspect of the inventive concept, there is provided a method of manufacturing a semiconductor device, the method including forming a stacked structure on a substrate by alternately stacking a plurality of sacrificial layers and a plurality of nanosheet layers, forming dummy gate structures, at least one of which is arranged at different intervals with respect to at least some adjacent dummy gate structures, on the stacked structure, performing first etching in which the dummy gate structures are used as an etch mask, chlorine gas is used as a first etch gas, and plasma is formed to expose an upper surface of a lowermost layer of the stacked structure, performing second etching in which the dummy gate structures are used as an etch mask, an interhalogen gas is used as a second etch gas, and plasma is formed to expose an upper surface of the substrate, separating the plurality of nanosheet layers into a plurality of nanosheets by forming recesses passing through the stacked structure by the first and second etchings, forming source/drain regions in the recesses, forming a gate space by removing the plurality of sacrificial layers and the dummy gate structures, and forming a gate dielectric layer and a gate electrode to fill the gate space.

According to another aspect of the inventive concept, there is provided a method of manufacturing a semiconductor device, the method including forming a stacked structure on a substrate by alternately stacking a plurality of sacrificial layers and a plurality of semiconductor layers, forming mask patterns, at least one of which is arranged at different intervals with respect to at least some adjacent mask patterns, on the stacked structure, performing first etching in which the mask patterns are used as an etch mask, chlorine gas is used as a first etch gas, and first plasma is formed to expose an upper surface of a lowermost layer of the stacked structure, performing second etching in which the mask patterns are used as an etch mask, an interhalogen gas is used as a second etch gas, and plasma is formed to expose an upper surface of the substrate, forming a first recess and a second recess passing through the stacked structure by the first and second etchings, removing the mask patterns and the plurality of sacrificial layers and forming a gate dielectric layer and a word line, forming a first source/drain region at one end of each of the plurality of semiconductor layers and filling the first recess to form a bit line, and forming a second source/drain region at another end of each of the plurality of semiconductor layers and filling the second recess to form a capacitor structure.

### BRIEF DESCRIPTION OF THE DRAWINGS

Embodiments will be more clearly understood from the following detailed description taken in conjunction with the accompanying drawings in which:

FIG. 1 is a flowchart of a selective thin-film etching method according to an embodiment;

FIG. 2 is a cross-sectional view illustrating a plasma etching apparatus used in the selective thin-film etching method of FIG. 1;

FIGS. 3 to 7 are cross-sectional views illustrating an example process sequence of the selective thin-film etching method of FIG. 1;

FIGS. 8 to 10 are diagrams showing etching characteristics of the selective thin-film etching method of FIG. 1;

FIG. 11 is a flowchart of a method of manufacturing a semiconductor device, according to an embodiment;

FIGS. 12 to 20 are cross-sectional views illustrating an example process sequence of the method of manufacturing a semiconductor device in FIG. 11;

FIG. 21 is a flowchart of a method of manufacturing a semiconductor device, according to another embodiment; and

FIGS. 22 to 30 are cross-sectional views illustrating an example process sequence of the method of manufacturing a semiconductor device in FIG. 21.

### DETAILED DESCRIPTION OF THE EMBODIMENTS

Embodiments will be described in detail with reference to the accompanying drawings.

For reference, the term “high selectivity” as used herein refers to an etch selectivity of about 10:1 or more. In contrast, the term “low selectivity” refers to an etch selectivity of less than about 10:1.

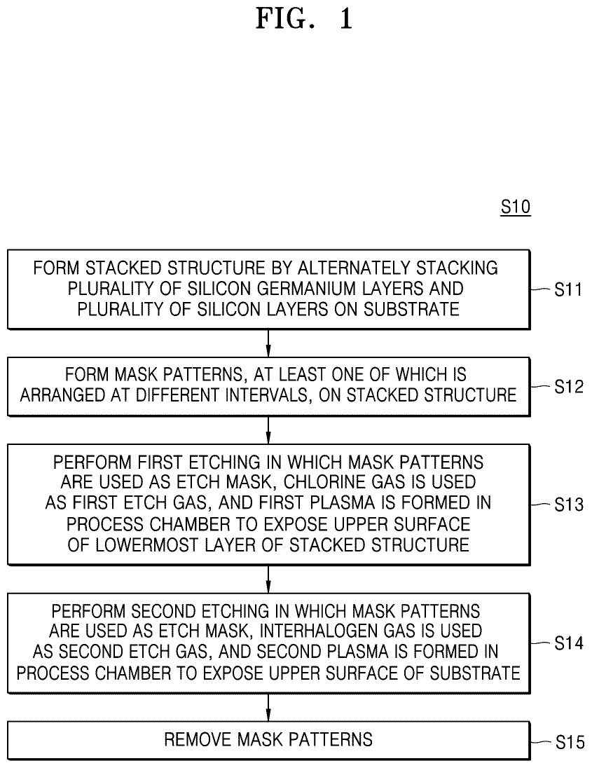

In addition, in the flowcharts (FIGS. 1, 11, and 21) described below, when a certain embodiment is implemented differently, a specific process sequence may be performed differently from a sequence described herein. For example, two consecutively described processes may be performed substantially at the same time or performed in an order opposite to the described order.

FIG. 1 is a flowchart of a selective thin-film etching method S10 according to an embodiment.

Referring to FIG. 1, the selective thin-film etching method S10 may include first to fifth operations S11 to S15.

The selective thin-film etching method S10 according to the inventive concept may include the first operation S11 of forming a stacked structure on a substrate by alternately stacking a plurality of silicon germanium layers and a plurality of silicon layers, the second operation S12 of forming mask patterns, at least one of which is arranged at different intervals with respect to at least some adjacent mask patterns, on the stacked structure, the third operation S13 of performing first etching in which the mask patterns are used as an etch mask, chlorine gas is used as a first etch gas, and first plasma is formed in a process chamber to expose an upper surface of a lowermost layer of the stacked structure, the fourth operation S14 of performing second etching in which the mask patterns are used as an etch mask, an interhalogen gas is used as a second etch gas, and second plasma is formed in the process chamber to expose an upper surface of the substrate, and the fifth operation S15 of removing the mask patterns.

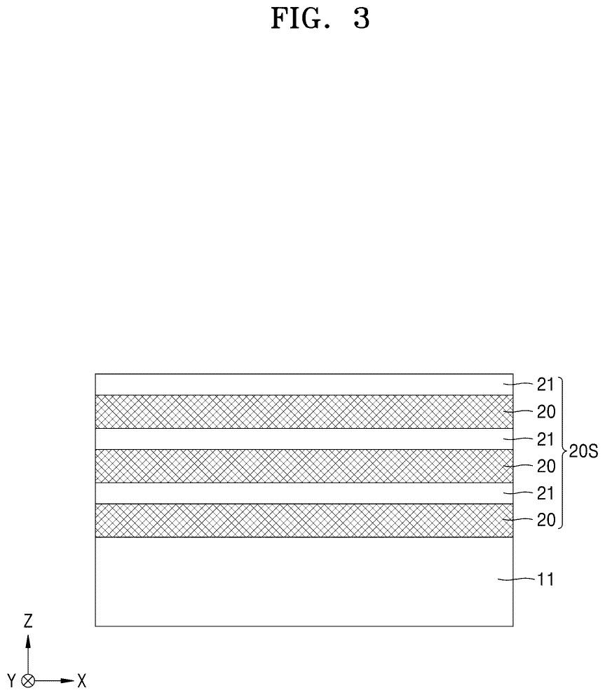

The technical features of the first to fifth operations S11 to S15 are described in detail below with reference to FIGS. 3 to 7.

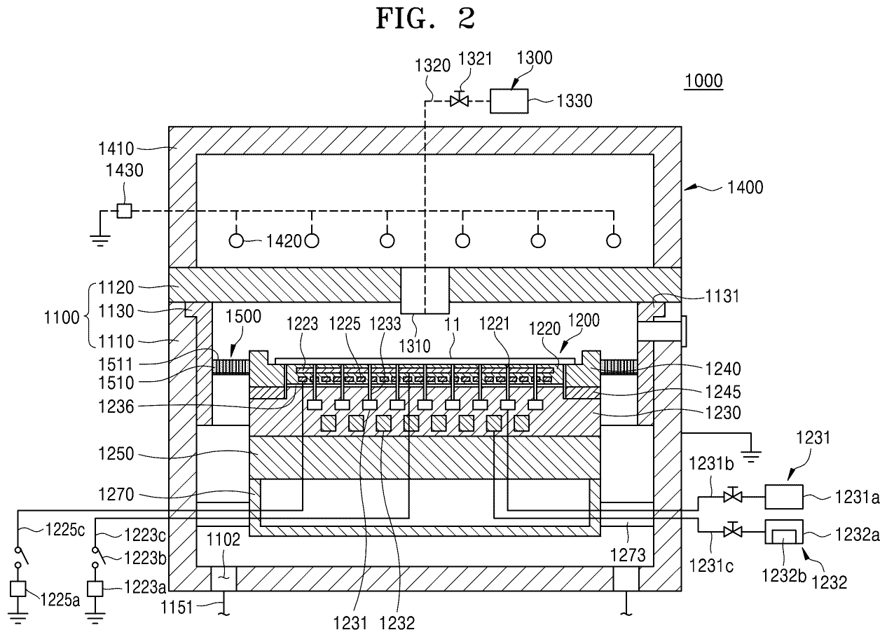

FIG. 2 is a cross-sectional view illustrating a plasma etching apparatus 1000 used in the selective thin-film etching method of FIG. 1.

Referring to FIG. 2, the plasma etching apparatus 1000 may include a process chamber 1100, a support unit 1200, a gas supply unit 1300, a plasma source 1400, and an exhaust unit 1500.

The plasma etching apparatus 1000 may process a substrate 11 by using plasma. For example, the plasma etching apparatus 1000 may perform an etching process on the substrate 11.

In an embodiment, the plasma etching apparatus 1000 that generates plasma by using an inductively coupled plasma method and etches the substrate 11 is described. However, the embodiment is not limited thereto and may be applied to other types of plasma etching apparatus 1000 that process the substrate 11 by using plasma, such as a capacitively coupled plasma method or a remote plasma method.

The process chamber 1100 may have a process space for processing the substrate 11 therein. The process chamber 1100 may include a housing 1110, a cover 1120, and a liner 1130.

The housing 1110 may have an internal space with an opened upper surface. The internal space of the housing 1110 may be provided as a process space where a substrate processing process is performed. The housing 1110 may include a metal material. The housing 1110 may include aluminum. The housing 1110 may be grounded. An exhaust hole 1102 may be formed in the bottom surface of the housing 1110. The exhaust hole 1102 may be connected to an exhaust line 1151. Reaction by-products generated during the process and gases remaining in the internal space of the housing 1110 may be discharged to the outside through the exhaust line 1151. The interior of the housing 1110 may be depressurized to a certain pressure through the exhaust process.

The cover 1120 may cover the opened upper surface of the housing 1110. The cover 1120 may be provided in a plate shape and may seal the internal space of the housing 1110. The cover 1120 may include a dielectric window.

The liner 1130 may be provided inside the housing 1110. The liner 1130 may have an internal space with an opened upper surface and an opened lower surface. The liner 1130 may be provided in a cylindrical shape. The liner 1130 may have a radius corresponding to the inner surface of the housing 1110. The liner 1130 may be provided along the inner surface of the housing 1110. A support ring 1131 may be formed at the upper end of the liner 1130. The support ring 1131 may be provided as a ring-shaped plate and may protrude outward from the liner 1130 along the circumference of the liner 1130. The support ring 1131 may be arranged at the upper end of the housing 1110 and may support the liner 1130.

The liner 1130 may include the same material as a material of the housing 1110. The liner 1130 may include aluminum. The liner 1130 may protect the inner surface of the housing 1110. For example, arc discharge may occur inside the process chamber 1100 during a process in which a process gas is excited. The arc discharge may damage peripheral devices. The liner 1130 may protect the inner surface of the housing 1110 to prevent the inner surface of the housing 1110 from being damaged by the arc discharge. In addition, the liner 1130 may prevent reaction by-products generated during the substrate processing process from being deposited on an inner wall of the housing 1110.

The support unit 1200 may support the substrate 11 in the process space inside the process chamber 1100. For example, the support unit 1200 may be arranged inside the housing 1110. The support unit 1200 may be provided in an electrostatic chuck method that uses an electrostatic force to adsorb the substrate 11. Alternatively, the support unit 1200 may support the substrate 11 in various methods, such as mechanical clamping. Hereinafter, the support unit 1200 provided in an electrostatic chuck method is described.

The support unit 1200 may include a first support plate 1220, an electrostatic electrode 1223, a heater 1225, a second support plate 1230, a focus ring 1240, a conductive pad 1245, a dielectric plate 1250, and a lower cover 1270. The support unit 1200 may be spaced upward from the bottom surface of the housing 1110 within the process chamber 1100.

The first support plate 1220 may be positioned at the upper end of the support unit 1200. The first support plate 1220 may include a disk-shaped dielectric. The substrate 11 may be placed on the upper surface of the first support plate 1220. The upper surface of the first support plate 1220 may have a radius less than a radius of the substrate 11. A first supply path 1221, which is used as a passage through which a heat transfer gas is supplied to the lower surface of the substrate 11, may be formed in the first support plate 1220. The electrostatic electrode 1223 and the heater 1225 may be buried in the first support plate 1220.

The electrostatic electrode 1223 may be positioned above the heater 1225. The electrostatic electrode 1223 may be electrically connected to a first lower power source 1223a. An electrostatic force may be applied between the electrostatic electrode 1223 and the substrate 11 by electric current applied to the electrostatic electrode 1223, and the substrate 11 may be adsorbed onto the first support plate 1220 by the electrostatic force.

The heater 1225 may be electrically connected to a second lower power source 1225a. The heater 1225 may generate heat by resisting electric current applied from the second lower power source 1225a. The generated heat may be transferred to the substrate 11 through the first support plate 1220. The substrate 11 may be maintained at a certain temperature by the heat generated by the heater 1225. The heater 1225 may include a spiral coil. The second support plate 1230 may be positioned below the first support plate 1220. The lower surface of the first support plate 1220 and the upper surface of the second support plate 1230 may be bonded to each other by an adhesive 1236.

The second support plate 1230 may be arranged below the first support plate 1220, may support the first support plate 1220, and may be connected to the first support plate 1220. A first circulation path 1231, a second circulation path 1232, and a second supply path 1233 may be formed in the second support plate 1230. The first circulation path 1231 may be provided as a passage through which a heat transfer gas circulates. The second circulation path 1232 may be provided as a passage through which a cooling fluid circulates. The second supply path 1233 may connect the first circulation path 1231 to the first supply path 1221. The first circulation path 1231 may be provided as a passage through which a heat transfer gas circulates. The first circulation path 1231 may be formed within the second support plate 1230 in a spiral shape. Alternatively, the first circulation path 1231 may be arranged so that ring-shaped paths having different radii have the same center. The first circulation paths 1231 may communicate with each other. The first circulation paths 1231 may be formed at the same height.

The first circulation path 1231 may be connected to a heat transfer medium storage unit 1231a through a heat transfer medium supply line 1231b. A heat transfer medium may be stored in the heat transfer medium storage unit 1231a. The heat transfer medium may include an inert gas. In some embodiments, the heat transfer medium may include helium gas. The helium gas may be supplied to the first circulation path 1231 through the heat transfer medium supply line 1231b and supplied to the lower surface of the substrate 11 sequentially through the second supply path 1233 and the first supply path 1221. The helium gas may act as a medium that helps heat exchange between the substrate 11 and the first support plate 1220. Therefore, the overall temperature of the substrate 11 becomes uniform.

The second circulation path 1232 may be connected to a cooling fluid storage unit 1232a through a cooling fluid supply line 1232c. The cooling fluid may be stored in the cooling fluid storage unit 1232a. A cooler 1232b may be provided in the cooling fluid storage unit 1232a. The cooler 1232b may cool the cooling fluid to a certain temperature. Alternatively, the cooler 1232b may be installed on the cooling fluid supply line 1232c. The cooling fluid supplied to the second circulation path 1232 through the cooling fluid supply line 1232c may circulate along the second circulation path 1232 and cool the second support plate 1230. The second support plate 1230 may cool the first support plate 1220 and the substrate 11 together while being cooled so that the substrate 11 may be maintained at a certain temperature.

The focus ring 1240 may be arranged at an edge area of the support unit 1200. The focus ring 1240 may have a ring shape and may be provided to surround the first support plate 1220. For example, the focus ring 1240 may be arranged along the circumference of the first support plate 1220 to support an edge area of the substrate 11. The focus ring 1240 may have an upper edge area that protrudes in a ring shape, and thus, may guide plasma to be focused onto the substrate 11.

The focus ring 1240 may extend from the upper surface of the conductive pad 1245 by a certain distance. The lower surface of the focus ring 1240 may come into direct contact with the upper surface of the conductive pad 1245.

The dielectric plate 1250 may be positioned below the second support plate 1230. The dielectric plate 1250 may include a dielectric material and may electrically insulate the second support plate 1230 and the lower cover 1270 from each other.

The lower cover 1270 may be positioned at the lower end of the support unit 1200. The lower cover 1270 may be spaced upward from the bottom surface of the housing 1110. The lower cover 1270 may have an internal space with an opened upper surface. The upper surface of the lower cover 1270 may be covered by the dielectric plate 1250. Accordingly, the outer radius of the cross-section of the lower cover 1270 may be equal to the outer radius of the dielectric plate 1250. A lift pin or the like, which receives the returned substrate 11 from an external return member and seats the substrate 11 onto the support unit 1200, may be positioned in the internal space of the lower cover 1270.

The lower cover 1270 may have a connection member 1273. The connection member 1273 may connect the outer surface of the lower cover 1270 to the inner wall of the housing 1110. A plurality of connection members 1273 may be provided on the outer surface of the lower cover 1270 at regular intervals. The connection member 1273 may support the support unit 1200 in the process chamber 1100. In addition, the connection member 1273 may be connected to the inner wall of the housing 1110 so that the lower cover 1270 is electrically grounded. A first power line 1223c connected to the first lower power source 1223a, a second power line 1225c connected to the second lower power source 1225a, the heat transfer medium supply line 1231b connected to the heat transfer medium storage unit 1231a, and the cooling fluid supply line 1232c connected to the cooling fluid storage unit 1232a may extend into the lower cover 1270 through the internal space of the connection member 1273.

The gas supply unit 1300 may supply the process gas to the process space inside the process chamber 1100. The gas supply unit 1300 may include a gas supply nozzle 1310, a gas supply line 1320, and a gas storage unit 1330. The gas supply nozzle 1310 may be installed in the central portion of the cover 1120. A spray hole may be formed in the lower surface of the gas supply nozzle 1310. The spray hole may be positioned below the cover 1120 and may supply the process gas to the process chamber 1100. The gas supply line 1320 may connect the gas supply nozzle 1310 to the gas storage unit 1330. The gas supply line 1320 may supply the process gas stored in the gas storage unit 1330 to the gas supply nozzle 1310. A valve 1321 may be installed in the gas supply line 1320. The valve 1321 may open and close the gas supply line 1320 and may control the flow rate of the process gas supplied through the gas supply line 1320.

The plasma source 1400 may generate plasma from the process gas supplied to the process space inside the process chamber 1100. The plasma source 1400 may be provided outside the process space of the process chamber 1100. An inductively coupled plasma source may be used as the plasma source 1400. The plasma source 1400 may include an antenna space 1410, an antenna 1420, and a plasma power source 1430. The antenna space 1410 may be provided in a cylindrical shape with an opened bottom. The antenna space 1410 may be provided to have a diameter corresponding to the process chamber 1100. The lower end of the antenna space 1410 may be detachable from the cover 1120.

The antenna 1420 may be arranged inside the antenna space 1410. The antenna 1420 may be provided as a spiral coil wound several times and may be connected to the plasma power source 1430. The antenna 1420 may receive power from the plasma power source 1430. The plasma power source 1430 may be positioned outside the process chamber 1100. The antenna 1420, to which power is supplied, may form an electromagnetic field in the process space of the process chamber 1100. The process gas (first and second etch gases described below) may be excited into a plasma state by the electromagnetic field.

The exhaust unit 1500 may be positioned between the inner wall of the housing 1110 and the support unit 1200. The exhaust unit 1500 may include an exhaust plate 1510 having a through hole 1511 formed therein. The exhaust plate 1510 may be provided in an annular ring shape. A plurality of through holes 1511 may be formed in the exhaust plate 1510. The process gas supplied to the housing 1110 may be exhausted to the exhaust hole 1102 through the through hole 1511 of the exhaust plate 1510. The flow of the process gas may be controlled according to the shape of the exhaust plate 1510 and the shape of the through hole 1511.

In a selective thin-film etching process and a method of manufacturing a semiconductor device, which are to be described below, the plasma etching apparatus 1000 described above may be used to etch the stacked structure in an accurate pattern on the exposed surface of the stacked structure, in which different materials are alternately stacked, by a plasma etching process using an etch gas with a high selectivity. This is described in detail below.

FIGS. 3 to 7 are cross-sectional views illustrating an example process sequence of the selective thin-film etching method of FIG. 1.

Referring to FIG. 3, a stacked structure 20S may be formed on a substrate 11 by alternately stacking a plurality of silicon germanium layers 20 and a plurality of silicon layers 21.

The substrate 11 may be a circular wafer including silicon (Si). For example, the substrate 11 may include crystalline silicon, polycrystalline silicon, or amorphous silicon. In some embodiments, the substrate 11 may have a silicon-on-insulator (SOI) structure. In addition, the substrate 11 may include a conductive area, for example, an impurity-doped well or an impurity-doped structure.

In some embodiments, the plurality of silicon germanium layers 20 and the plurality of silicon layers 21 may each be formed on the substrate 11 by an epitaxy process. The epitaxy process may be chemical vapor deposition (CVD), such as vapor phase epitaxy (VPE), ultra-high vacuum chemical vapor deposition (UHV-CVD), molecular beam epitaxy, or a combination thereof. In the epitaxy process, a liquid or gaseous precursor may be used as a precursor required for forming the plurality of silicon germanium layers 20 and the plurality of silicon layers 21.

The plurality of silicon germanium layers 20 and the plurality of silicon layers 21 may include materials having an etch selectivity with respect to each other. In addition, as described above, the substrate 11 and the plurality of silicon layers 21 may include substantially the same material.

The structure in which the plurality of silicon germanium layers 20 and the plurality of silicon layers 21 are stacked may be referred to as the stacked structure 20S.

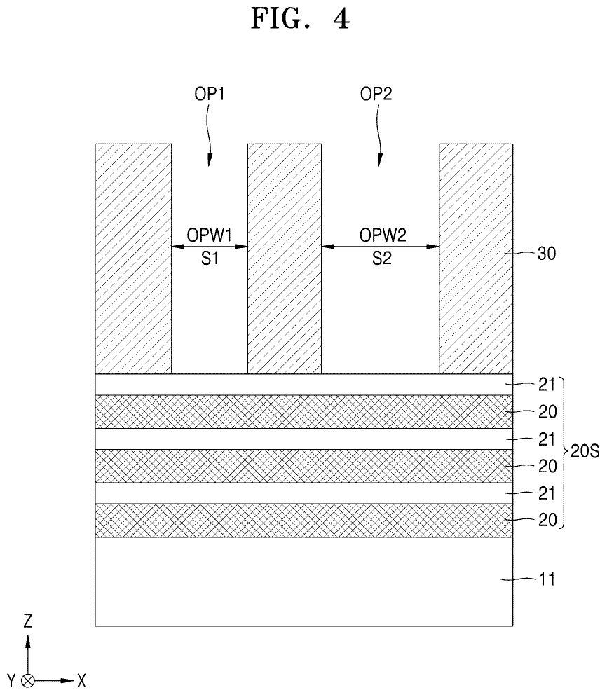

Referring to FIG. 4, mask patterns 30, at least one of which is arranged at different intervals with respect to at least some adjacent mask patterns, may be formed on the stacked structure 20S.

The mask patterns 30 may be formed on the stacked structure 20S. The mask patterns 30 may have a first opening OP1 and a second opening OP2 for etching the stacked structure 20S. The first opening OP1 may have a first opening width OPW1, and the second opening OP2 may have a second opening width OPW2 that is greater than the first opening width OPW1. Accordingly, the mask patterns 30 may be formed to have a first interval S1 and a second interval S2 that is greater than the first interval S1. That is, the mask patterns 30, at least one of which is arranged at different intervals with respect to at least some adjacent mask patterns, may be formed.

The mask patterns 30 may include materials having an etch selectivity with respect to the plurality of silicon germanium layers 20 and the plurality of silicon layers 21. In some embodiments, the mask patterns 30 may each include silicon nitride. That is, the mask patterns 30 may be a hard mask.

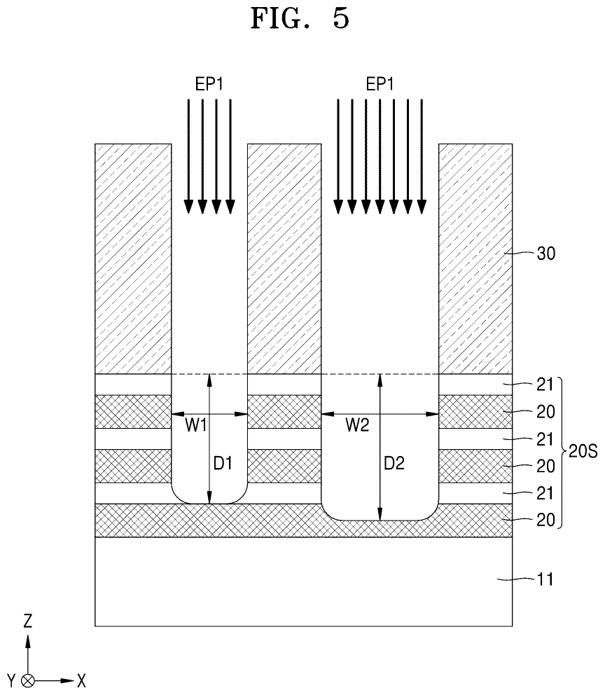

Referring to FIG. 5, a first etching process EP1 may be performed by using the mask patterns 30 as an etch mask.

The first etching process EP1 may be a dry etching process using the plasma etching apparatus 1000 described above.

The first etching process EP1 in which chlorine gas (Cl₂) is used as a first etch gas and first plasma is formed in the process chamber 1100 to expose the upper surface of the lowermost layer (i.e., the silicon germanium layer) of the stacked structure 20S may be performed on the first opening OP1 and the second opening OP2 of the mask patterns 30.

The chlorine gas (Cl₂) may be used alone as the first etch gas, or the chlorine gas (Cl₂) may be mixed with nitrogen gas (N₂) and the mixed gas may be used as the first etch gas. The nitrogen gas (N₂) may be referred to as a base gas.

Because the second opening width OPW2 of the second opening OP2 is relatively greater than the first opening width OPW1 of the first opening OP1, a recess having a first width W1 and a first depth D1 may be formed in an area corresponding to the first opening OP1 and a recess having a second width W2 and a second depth D2 may be formed in an area corresponding to the second opening OP2.

The first etching process EP1 is an etching process with a low selectivity, and the stacked structure 20S may be etched in proportion to an etch time. Specifically, in the first etching process EP1, the etch selectivity of the first etch gas with respect to silicon germanium/silicon may be in a range of about 1 to about 2.

Because the exposed surface of the area corresponding to the second opening OP2 is relatively large, the second depth D2 by the first etching process EP1 may be greater than the first depth D1. Accordingly, a portion of the lowermost layer (i.e., the silicon germanium layer) of the stacked structure 20S may be overetched in the area corresponding to the second opening OP2. This is for completely removing the layer (i.e., the silicon layer) immediately above the lowermost layer (i.e., the silicon germanium layer) in the area corresponding to the first opening OP1.

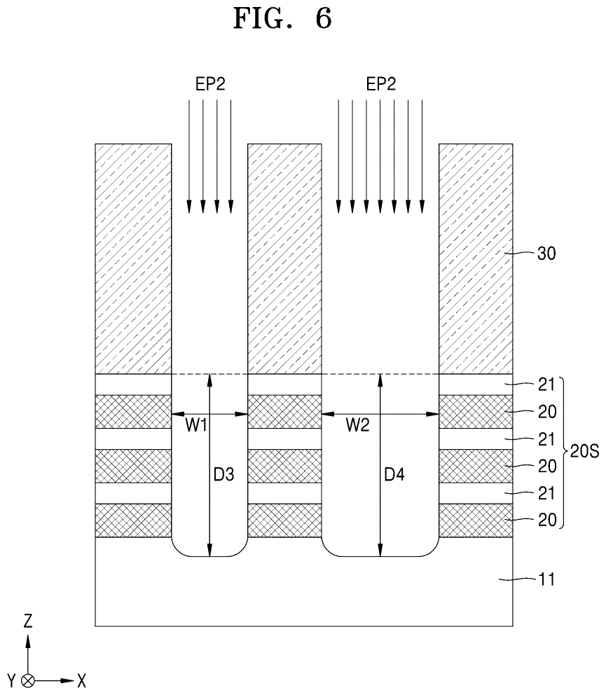

Referring to FIG. 6, a second etching process EP2 may be performed by using the mask patterns 30 as an etch mask.

The second etching process EP2 may be a dry etching process using the plasma etching apparatus 1000 described above.

The second etching process EP2 in which an interhalogen gas is used as a second etch gas and second plasma is formed in the process chamber 1100 to expose the upper surface of the substrate 11 through the stacked structure 20S may be performed on the first opening OP1 and the second opening OP2 of the mask patterns 30.

The interhalogen gas may be used alone as the second etch gas, or the interhalogen gas may be mixed with nitrogen gas (N₂), which is a base gas, and the mixed gas may be used as the second etch gas. The interhalogen gas refers to a gas in which halogen elements (F, Cl, Br, or I) are bonded to each other.

The second etch gas may be any one selected from BrF₅, IF₅, and IF₇ gases, and more specifically, the second etch gas may use IF₇ gas represented by Chemical Structural Formula 1 below.

### [Chemical Structural Formula 1]

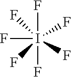

Because a molar mass (259.9 g/mol) of the IF₇ gas is relatively greater than molar masses of other interhalogen gases, etching characteristics may be excellent.

To perform the second etching process EP2, a process pressure of the process chamber 1100 in the plasma etching apparatus 1000 may be in a range of about 1 m Torr to about 1 Torr and a process temperature of the process chamber 1100 may be in a range of about 25° C. to about 100° C.

The second opening width OPW2 of the second opening OP2 is relatively greater than the first opening width OPW1 of the first opening OP1, but the second etching process EP2 is an etching process having a high selectivity, and thus, a recess having a first width W1 and a third depth D3 may be formed in an area corresponding to the first opening OP1 and a recess having a second width W2 and a fourth depth D4 may be formed in an area corresponding to the second opening OP2.

The second etching process EP2 is an etching process with a high selectivity, and the stacked structure 20S may be etched according to the type of material constituting an etch target layer. Specifically, in the second etching process EP2, the etch selectivity of the second etch gas with respect to silicon germanium/silicon may be in a range of about 10 to about 40.

Therefore, regardless of the sizes of the exposed surfaces of the areas corresponding to the first opening OP1 and the second opening OP2, the third depth D3 and the fourth depth D4 by the second etching process EP2 may be substantially equal to each other. In some embodiments, a portion of the substrate 11 may be overetched to completely remove the lowermost layer (i.e., the silicon germanium layer) of the stacked structure 20S.

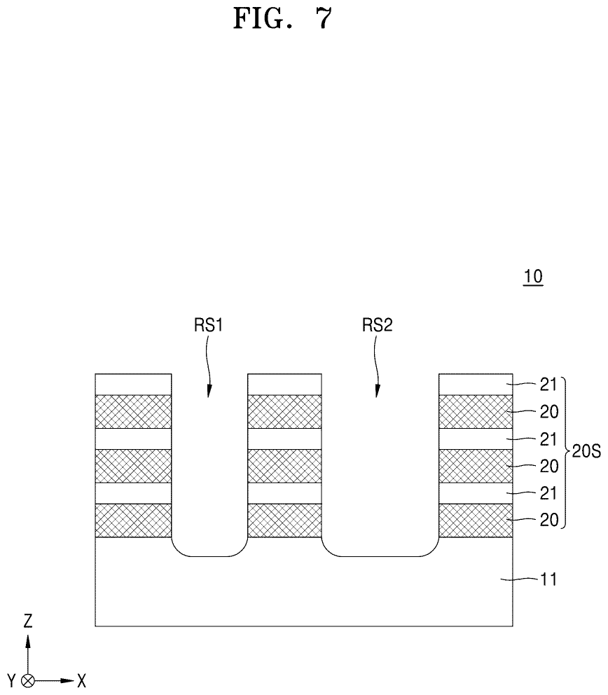

Referring to FIG. 7, the mask patterns 30 may be removed from the stacked structure 20S.

The mask patterns 30 may each include silicon nitride. In addition, the etch selectivity of the second etch gas with respect to silicon germanium/silicon nitride may be in a range of about 20 to about 60. Accordingly, while the second etching process EP2 is performed, the mask patterns 30 may be maintained without being removed. That is, a first recess RS1 and a second recess RS2 that completely pass through the stacked structure 20S and have different widths may be formed by using the mask patterns 30 as an etch mask.

After the first recess RS1 and the second recess RS2 are formed, the mask patterns 30 may be removed. As the mask patterns 30 are removed, the upper surface of the stacked structure 20S may be exposed. Accordingly, an etching result 10 including the first recess RS1 and the second recess RS2 may be formed.

As described above, the selective thin-film etching method S10 according to the inventive concept may include forming the etching result 10 by etching an etch target layer to an accurate depth through a plasma etching process using an etch gas with a high selectivity (i.e., IF₇ gas) on the exposed surface of the lowermost layer (i.e., the silicon germanium layer) in the stacked structure 20S in which different material layers (i.e., the silicon germanium layer and the silicon layer) are alternately stacked.

Ultimately, the selective thin-film etching method S10 according to the inventive concept has an effect of improving productivity and cost reduction according to precise etching of the thin-film by etching a desired thin-film in an accurate pattern through a plasma etching process using an etch gas with a high selectivity in the mask patterns 30 having different intervals from each other.

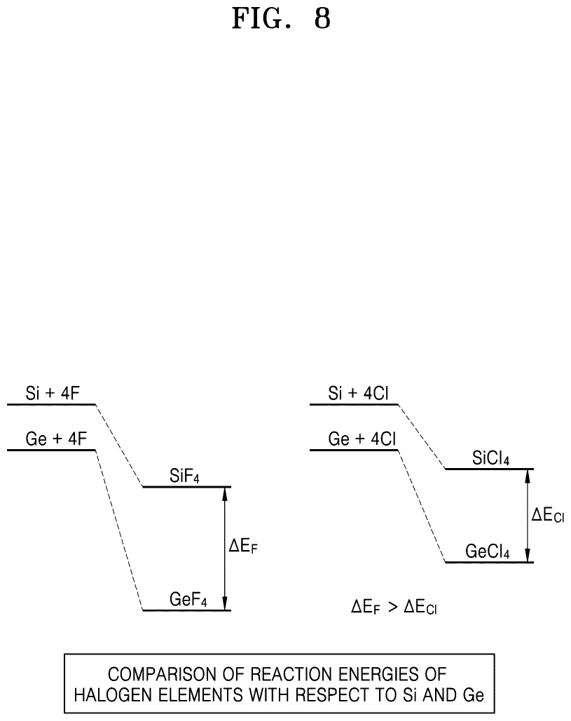

FIGS. 8 to 10 are diagrams showing etching characteristics of the selective thin-film etching method of FIG. 1.

FIG. 8 is a graph comparing reaction energies of halogen elements with respect to silicon (Si) and germanium (Ge).

The present application discloses a novel etch gas having a high etch selectivity with respect to silicon germanium/silicon in a thin-film etching process that performs dry etching (i.e., anisotropic etching) on a structure in which a plurality of silicon germanium layers and a plurality of silicon layers are stacked. This novel etch gas can be used for preventing non-etching or overetching and performing accurate etching to a target etch depth by using an etch gas with a high selectivity in a thin-film etching process.

This novel etch gas may include interhalogen gases. The interhalogen gas may be any one selected from BrF₅, IF₅, and IF₇ gases. Among them, IF₇ gas includes fluorine (F) that may increase an etch reactivity for silicon germanium.

FIG. 8 shows the difference in etch reactivity of fluorine (F) and chlorine (CI) for silicon (Si) and germanium (Ge). Because a reaction energy difference ΔE_{F} between etch reaction products, SiF₄ and GeF₄, is relatively greater than a reaction energy difference ΔE_{Cl} between SiCl₄ and GeCl₄, it may be predicted that the etch reaction energy difference between silicon (Si) and germanium (Ge) will increase when an etch gas including fluorine (F) is used.

Accordingly, it may be inferred that, when etched with silicon (Si) and germanium (Ge), the difference in etch reactivity for silicon germanium including these elements and silicon is great, and thus, the selectivity to silicon germanium/silicon is high. In addition, a recess with a large aspect ratio may be formed at a high etch rate by forming a fragment including a large molar mass of iodine (I) under the process conditions of the plasma etching apparatus.

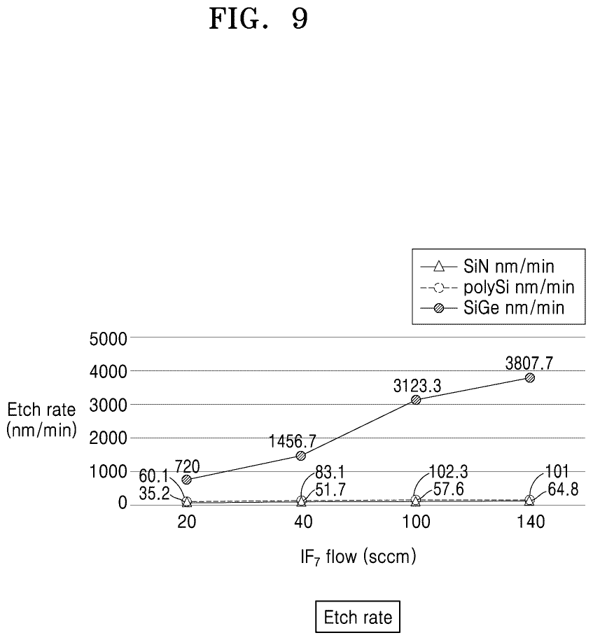

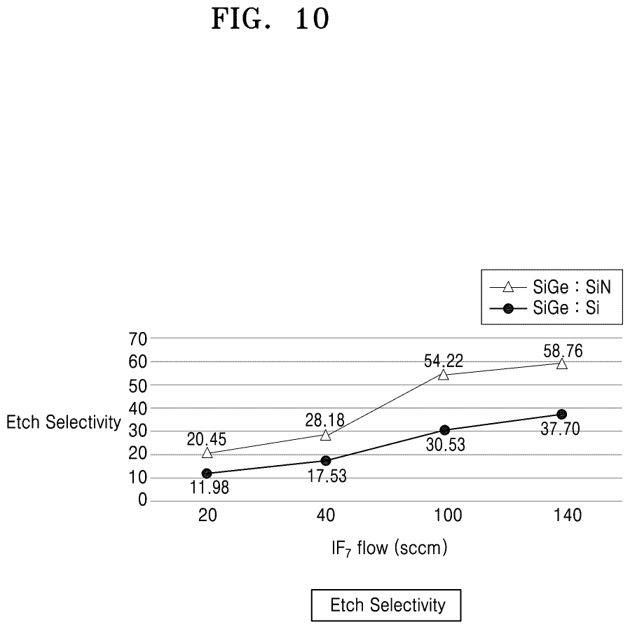

As a result, IF₇ gas may be relatively better as a novel etch gas compared to other gases. The etching characteristics (the etch rate and the etch selectivity) of the IF₇ gas are described in detail below with reference to FIGS. 9 and 10.

FIGS. 9 and 10 are a graph showing the etch rate according to material layers of IF₇ gas (FIG. 9) and a graph showing the etch selectivity (FIG. 10).

The etch rate refers to an etching speed and means the rate of change in thickness of a thin-film to be etched per unit time. IF₇ gas was supplied in a range of 20 sccm to 140 sccm, and an etch thickness (nm) per unit time (min) was measured.

As described above, in the case of the novel etch gas, IF₇ gas including fluorine (F) and iodine (I) with a large molar mass was supplied together with nitrogen gas (N₂), which was a base gas, so as to increase the etch reactivity with silicon germanium.

When the total flow rate of IF₇ gas and N₂ gas was fixed to 140 sccm and the flow rate of IF₇ gas was gradually increased, the etch selectivity with respect to silicon germanium/silicon was measured to be in a range of about 10 to about 40 and the etch selectivity with respect to silicon germanium/silicon nitride was measured to be in a range of about 20 to about 60.

The process conditions for verifying the etching characteristics of IF₇ gas may be that the process pressure of the process chamber 1100 in the plasma etching apparatus 1000 may be in a range of about 1 m Torr to about 1 Torr and the process temperature of the process chamber 1100 may be in a range of about 25° C. to about 100° C.

In addition, it was confirmed that both inductively coupled plasma and capacitively coupled plasma may be used as plasma sources to implement the etch selectivity characteristics of IF₇ gas.

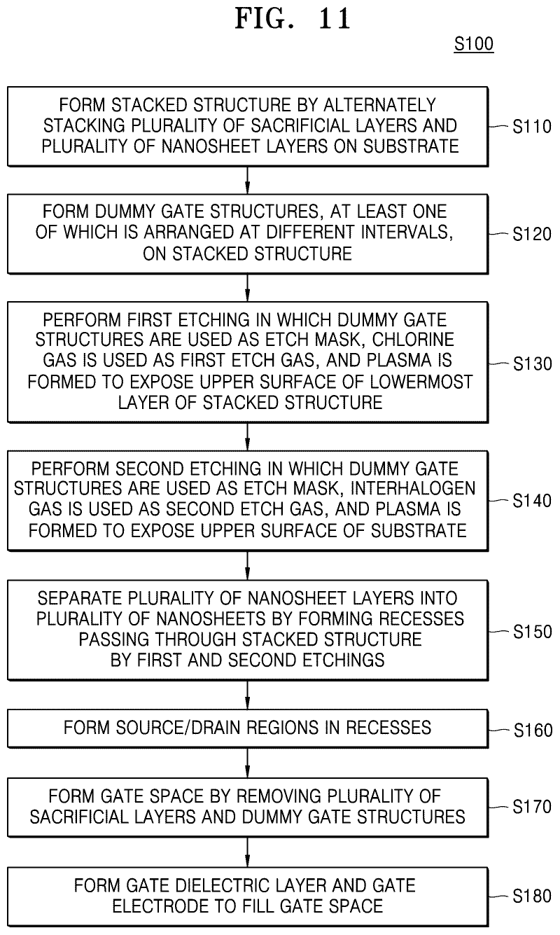

FIG. 11 is a flowchart of a method S100 of manufacturing a semiconductor device, according to an embodiment.

Referring to FIG. 11, the method S10 of manufacturing a semiconductor device, according to the inventive concept, may include first to eighth operations S110 to S180.

The method S100 of manufacturing a semiconductor device, according to the inventive concept, may include the first operation S110 of forming a stacked structure on a substrate by alternately stacking a plurality of sacrificial layers and a plurality of nanosheet layers, the second operation S120 of forming dummy gate structures, at least one of which is arranged at different intervals with respect to at least some adjacent dummy gate structures, on the stacked structure, the third operation S130 of performing first etching in which the dummy gate structures are used as an etch mask, chlorine gas is used as a first etch gas, and plasma is formed to expose an upper surface of the lowermost layer of the stacked structure, the fourth operation S140 of performing second etching in which the dummy gate structures are used as an etch mask, an interhalogen gas is used as a second etch gas, and plasma is formed to expose an upper surface of the substrate, the fifth operation S150 of separating the plurality of nanosheet layers into a plurality of nanosheets by forming recesses passing through the stacked structure by the first and second etchings, the sixth operation S160 of forming source/drain regions in the recesses, the seventh operation S170 of forming a gate space by removing the plurality of sacrificial layers and the dummy gate structures, and the eighth operation S180 of forming a gate dielectric layer and a gate electrode to fill the gate space.

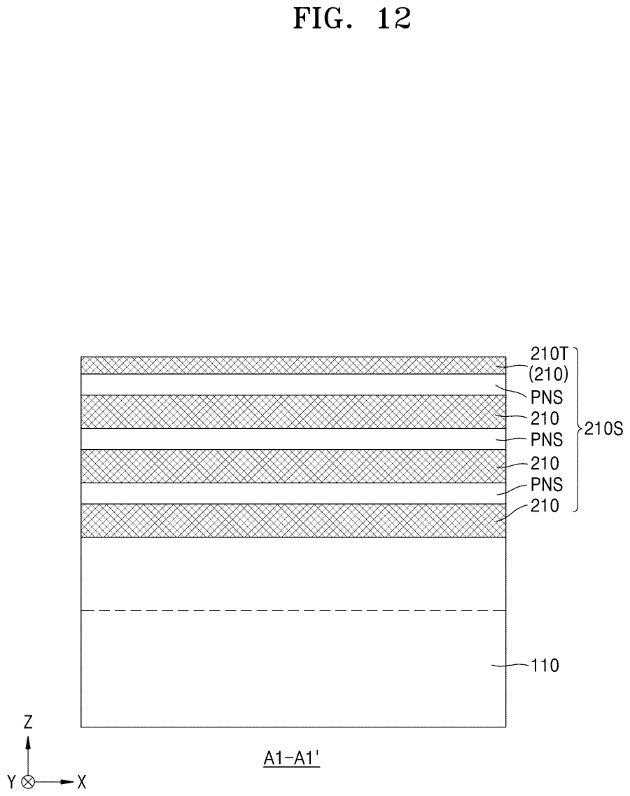

The technical features of the first to eighth operations S110 to S180 are described in detail below with reference to FIGS. 12 to 20.

FIGS. 12 to 20 are cross-sectional views illustrating an example process sequence of the method of manufacturing a semiconductor device in FIG. 11.

Referring to FIG. 12, a plurality of sacrificial layers 210 and a plurality of nanosheet layers PNS may be alternately formed on an upper surface of a substrate 110.

A structure in which the plurality of sacrificial layers 210 and the plurality of nanosheet layers PNS are stacked may be referred to as a nanosheet stack 210S.

In some embodiments, the sacrificial layers 210 and the nanosheet layers PNS may be formed by an epitaxy process. In addition, the sacrificial layer 210 and the nanosheet layer PNS may be made of materials having an etch selectivity with respect to each other. That is, the sacrificial layer 210 and the nanosheet layer PNS may be made of different materials. The sacrificial layer 210 may include silicon germanium, and the nanosheet layer PNS may include single crystalline silicon.

At least one of the plurality of sacrificial layers 210 may have a different thickness in a vertical direction Z from the remaining sacrificial layers 210. Specifically, a top sacrificial layer 210T may have a smaller thickness in the vertical direction Z than the remaining sacrificial layers 210.

The sacrificial layer 210 rather than the nanosheet layer PNS may be formed on the uppermost layer of the nanosheet stack 210S. In some embodiments, a protection layer (not shown) may be further formed to cover the top sacrificial layer 210T.

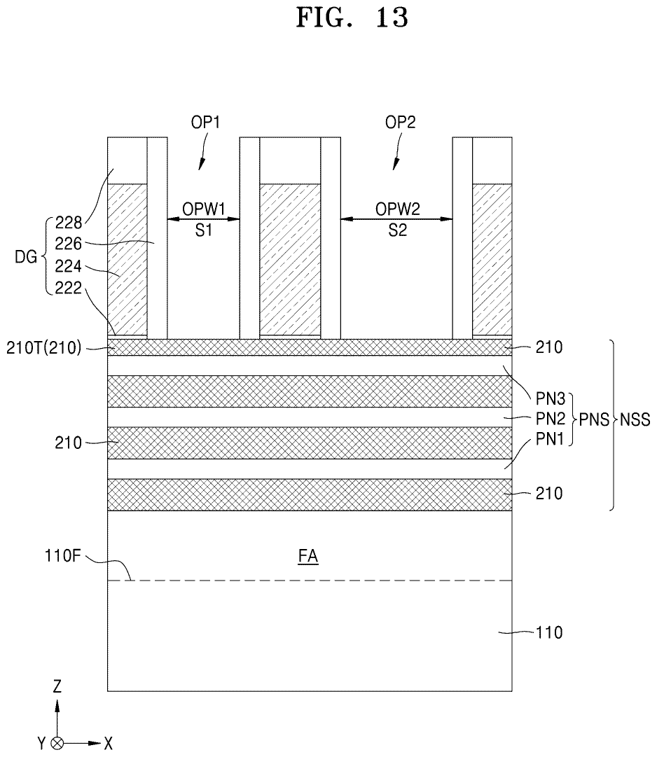

Referring to FIG. 13, after a hard mask pattern (not shown) is formed on the top sacrificial layer 210T, a device isolation layer (not shown) may be formed to define a fin-type active area FA on the substrate 110.

In the above process, the nanosheet layer PNS may include a first nanosheet layer PN1, a second nanosheet layer PN2, and a third nanosheet layer PN3, which are arranged on a first surface 110F of the substrate 110 and spaced apart from each other in the vertical direction Z. The sacrificial layers 210 may be respectively formed between the upper surface of the substrate 110 and the first nanosheet layer PN1, between the first nanosheet layer PN1 and the second nanosheet layer PN2, between the second nanosheet layer PN2 and the third nanosheet layer PN3, and on the upper surface of the third nanosheet layer PN3.

Next, sacrificial gate structures DG may be formed on the stacked structure NSS of the nanosheet layer PNS and the sacrificial layer 210. The sacrificial gate structures DG may each include a sacrificial dielectric layer pattern 222, a sacrificial gate line 224, a sacrificial gate spacer 226, and a sacrificial gate capping layer 228.

The sacrificial gate structure DG may have a first opening OP1 and a second opening OP2 for etching the stacked structure NSS. The first opening OP1 may have a first opening width OPW1, and the second opening OP2 may have a second opening width OPW2 that is greater than the first opening width OPW1. Accordingly, the sacrificial gate structures DG may be formed to have a first interval S1 and a second interval S2 that is greater than the first interval S1. That is, at least one of the sacrificial gate structures DG may be arranged at different intervals with respect to at least some adjacent sacrificial gate structures.

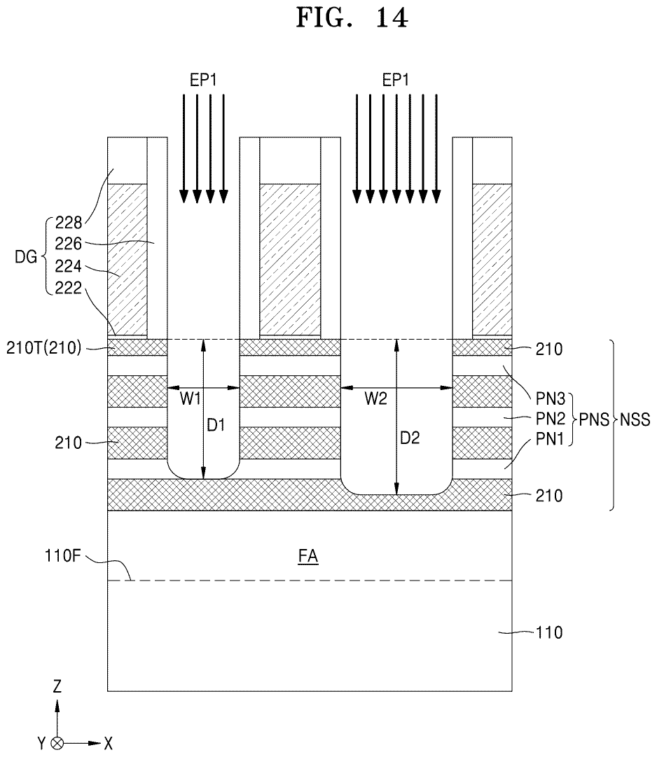

Referring to FIG. 14, a first etching process EP1 may be performed by using the sacrificial gate structures DG as an etch mask.

The first etching process EP1 may be a dry etching process using the plasma etching apparatus 1000 described above.

The first etching process EP1 in which chlorine gas (Cl₂) is used as a first etch gas and first plasma is formed in the process chamber 1100 to expose the upper surface of the lowermost layer (i.e., the sacrificial layer) of the stacked structure NSS may be performed on the first opening OP1 and the second opening OP2 of the sacrificial gate structures DG.

The chlorine gas (Cl₂) may be used alone as the first etch gas, or the chlorine gas (Cl₂) may be mixed with nitrogen gas (N₂) and the mixed gas may be used as the first etch gas. The nitrogen gas (N₂) may be referred to as a base gas.

Because the second opening width OPW2 of the second opening OP2 is relatively greater than the first opening width OPW1 of the first opening OP1, a recess having a first width W1 and a first depth D1 may be formed in an area corresponding to the first opening OP1 and a recess having a second width W2 and a second depth D2 may be formed in an area corresponding to the second opening OP2.

The first etching process EP1 is an etching process with a low selectivity, and the stacked structure NSS may be etched in proportion to an etch time. Specifically, in the first etching process EP1, the etch selectivity of the first etch gas with respect to silicon germanium/silicon may be in a range of about 1 to about 2.

Because the exposed surface of the area corresponding to the second opening OP2 is relatively large, the second depth D2 by the first etching process EP1 may be greater than the first depth D1. Accordingly, a portion of the lowermost layer (i.e., the sacrificial layer) of the stacked structure NSS may be overetched in the area corresponding to the second opening OP2. This is for completely removing the layer (i.e., the nanosheet layer) immediately above the lowermost layer (i.e., the sacrificial layer) in the area corresponding to the first opening OP1.

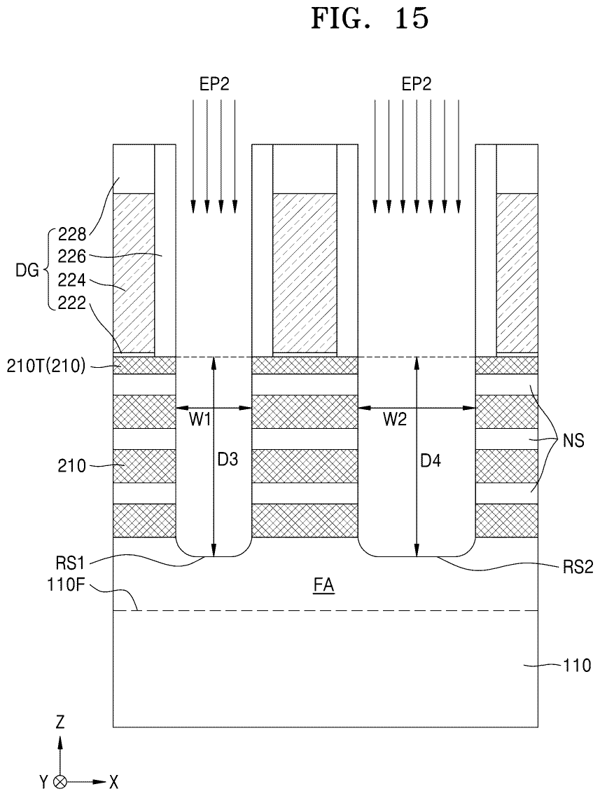

Referring to FIG. 15, a second etching process EP2 may be performed by using the sacrificial gate structures DG as an etch mask.

The second etching process EP2 may be a dry etching process using the plasma etching apparatus 1000 described above.

The second etching process EP2 in which an interhalogen gas is used as a second etch gas and second plasma is formed in the process chamber 1100 to expose the upper surface of the substrate 110 through the stacked structure NSS may be performed on the first opening OP1 and the second opening OP2 of the sacrificial gate structure DG.

The interhalogen gas may be used alone as the second etch gas, or the interhalogen gas may be mixed with nitrogen gas (N₂), which is a base gas, and the mixed gas may be used as the second etch gas.

The second etch gas may be any one selected from BrF₅, IF₅, and IF₇ gases, and more specifically, the second etch gas may use IF₇ gas. Because the molar mass of the IF₇ gas (259.9 g/mol) is relatively greater than the molar masses of other interhalogen gases, etching characteristics may be excellent.

To perform the second etching process EP2, the process pressure of the process chamber 1100 in the plasma etching apparatus 1000 may be in a range of about 1 m Torr to about 1 Torr, and the process temperature of the process chamber 1100 may be in a range of about 25° C. to about 100° C.

The second opening width OPW2 of the second opening OP2 is relatively greater than the first opening width OPW1 of the first opening OP1, but the second etching process EP2 is an etching process having a high selectivity, and thus, a recess having a first width W1 and a third depth D3 may be formed in an area corresponding to the first opening OP1 and a recess having a second width W2 and a fourth depth D4 may be formed in an area corresponding to the second opening OP2.

The second etching process EP2 is an etching process with a high selectivity, and the stacked structure NSS may be etched according to an etch material. Specifically, in the second etching process EP2, the etch selectivity of the second etch gas with respect to silicon germanium/silicon may be in a range of about 10 to about 40.

Therefore, regardless of the sizes of the exposed surfaces of the areas corresponding to the first opening OP1 and the second opening OP2, the third depth D3 and the fourth depth D4 by the second etching process EP2 may be substantially equal to each other. To completely remove the lowermost layer (i.e., the sacrificial layer) of the stacked structure NSS, a portion of the substrate 110 may be overetched.

A first recess RS1 and a second recess RS2 that completely pass through the stacked structure NSS may be formed by using the sacrificial gate structure DG as an etch mask.

As the first and second recesses RS1 and RS2 are formed, the plurality of nanosheet layers PNS may be separated into a plurality of nanosheets NS. For example, as the first and second recesses RS1 and RS2 are formed, a structure in which the plurality of sacrificial layers 210 and the plurality of nanosheets NS are alternately arranged on the fin-type active area FA may be formed.

In some embodiments, as illustrated, the first and second recesses RS1 and RS2 may include sidewalls that extend continuously and are aligned with opposite sidewalls of the sacrificial gate structure DG, for example, opposite sidewalls of the sacrificial gate spacer 226. In other words, the sidewalls of each of the plurality of nanosheets NS exposed by the first and second recesses RS1 and RS2 may be aligned with the sidewalls of the sacrificial gate spacer 226 to form a flat sidewall profile.

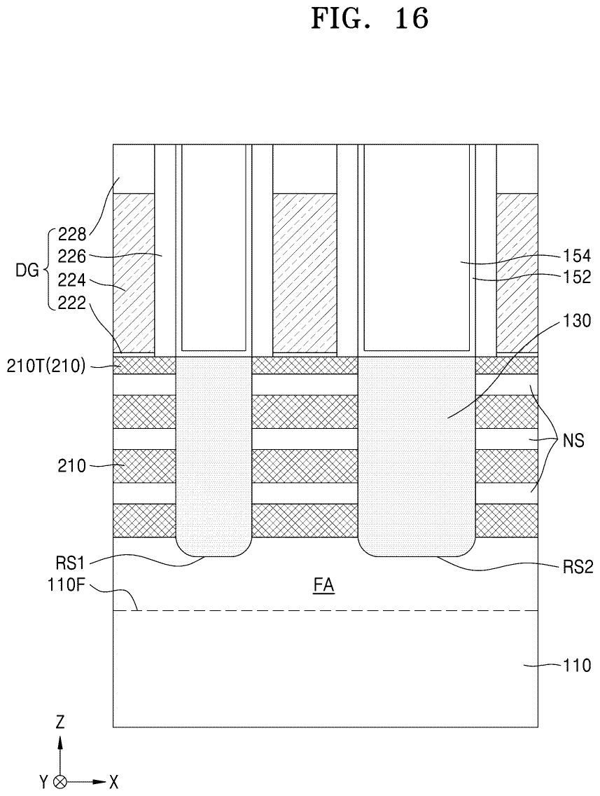

Referring to FIG. 16, a plurality of source/drain regions 130 may be formed in the first and second recesses RS1 and RS2.

In some embodiments, the source/drain regions 130 may be formed by growing a semiconductor material from the plurality of nanosheets NS, the sacrificial layer 210, and the surface of the substrate 110, which are exposed from the inner walls of the first and second recesses RS1 and RS2, through an epitaxy process.

The source/drain regions 130 may be formed with a relatively large thickness so as to fill the first and second recesses RS1 and RS2. The upper surface of the source/drain region 130 may be formed to be arranged at substantially the same vertical level as the upper surface of the top sacrificial layer 210T.

Next, a passivation layer 152, which covers the sacrificial gate structure DG and the source/drain region 130, and an inter-gate dielectric layer 154 may be formed. The passivation layer 152 may be formed with a small thickness, and the inter-gate dielectric layer 154 may be formed with a relatively large vertical level so as to fill a space between two adjacent sacrificial gate structures DG. The upper surface of the inter-gate dielectric layer 154 may be formed so as to be arranged at the same vertical level as the upper surface of the sacrificial gate structure DG.

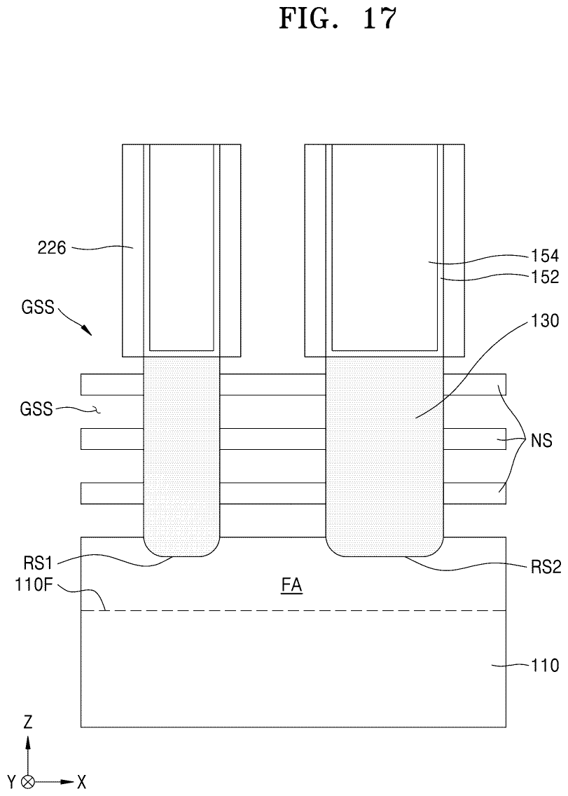

Referring to FIG. 17, the sacrificial gate capping layer 228, the sacrificial gate line 224, and the sacrificial dielectric layer pattern 222 may be removed.

Accordingly, a gate space GSS may be defined between two adjacent sacrificial gate spacers 226, and the sidewalls of the plurality of nanosheets NS and the upper surface of the top sacrificial layer 210T may be exposed in the gate space GSS.

Next, the plurality of sacrificial layers 210 remaining on the fin-type active region FA may be all removed through the gate space GSS to expose the upper surface of the fin-type active region FA, the upper and lower surfaces of the plurality of nanosheets NS, and the sidewalls of the source/drain region 130. The process of removing the plurality of sacrificial layers 210 may be a wet etching process using an etch selectivity between the plurality of sacrificial layers 210 and the plurality of nanosheets NS.

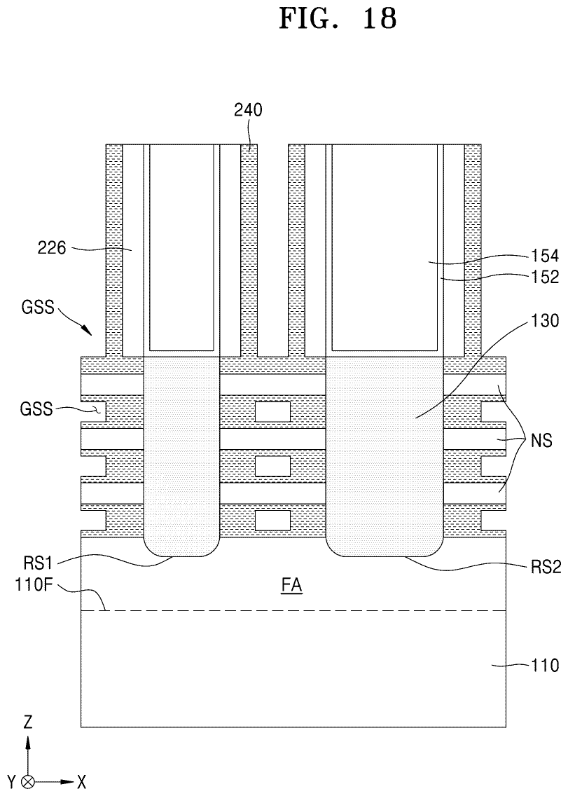

Referring to FIG. 18, a spacer forming layer 240 that conformally surrounds the gate space GSS may be formed.

The spacer forming layer 240 may be formed to contact between two adjacent sacrificial gate spacers 226, between two adjacent source/drain regions 130, and the upper and lower surfaces of the plurality of nanosheets NS.

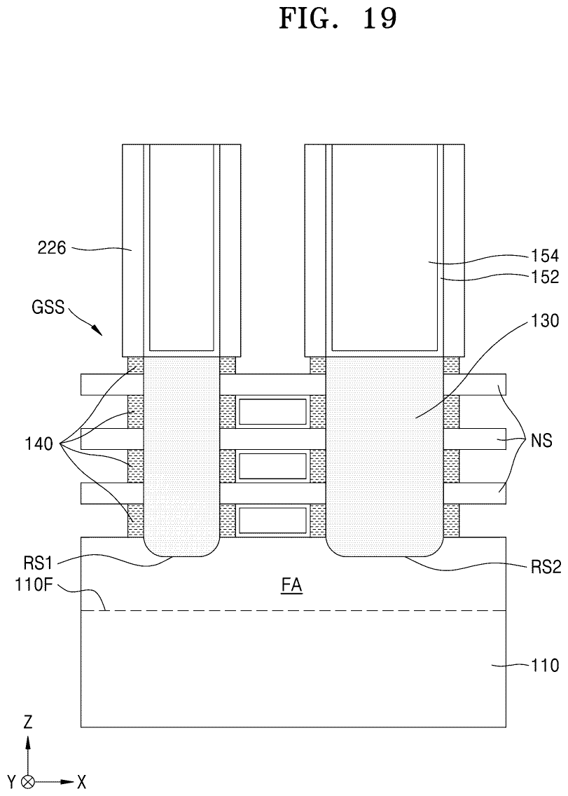

Referring to FIG. 19, an inner spacer 140 may be formed by removing a portion of the spacer forming layer 240.

In some embodiments, the inner spacer 140 may be formed in contact with the upper surface of the fin-type active region FA, the upper and lower surfaces of the plurality of nanosheets NS, and the sidewalls of the source/drain region 130. The process of removing a portion of the spacer forming layer 240 may be performed by an etching process using conditions having selective etching characteristics for the spacer forming layer 240.

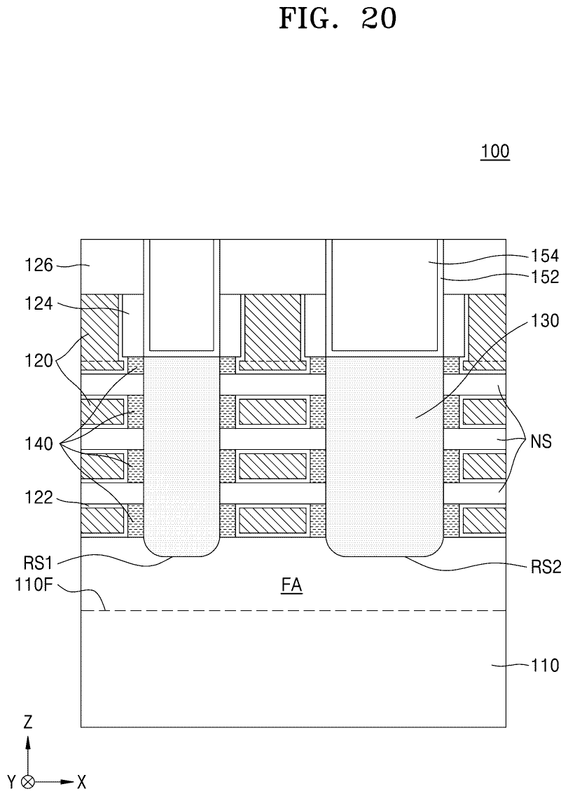

Referring to FIG. 20, a gate dielectric layer 122 may be formed on the exposed surfaces of the gate space GSS.

Next, a gate line 120 that fills the gate space GSS may be formed on the gate dielectric layer 122. For example, after a work function conductive layer (not shown) is conformally formed on the inner wall of the gate space GSS, a filling conductive layer (not shown) may be formed on the work function conductive layer to fill the gate space GSS.

Next, the gate line 120 may be formed by planarizing the upper portion of the filling conductive layer so that the upper surface of the inter-gate dielectric layer 154 is exposed.

Next, a portion of the upper side of each of the gate line 120, the gate dielectric layer 122, and the sacrificial gate spacer 226 may be removed, and a gate capping layer 126 may be formed above the gate space GSS. The remaining portion of the sacrificial gate spacer 226 may be referred to as an outer spacer 124.

The semiconductor device 100 according to the inventive concept, which is formed by the manufacturing process described above, may have a gate-all-around structure in which the gate line 120 surrounds the plurality of nanosheets NS.

Ultimately, the method S100 of manufacturing a semiconductor device, according to the inventive concept, has an effect of improving productivity and cost reduction according to precise etching of the thin-film by etching a desired thin-film in an accurate pattern through a plasma etching process using an etch gas with a high selectivity in the sacrificial gate structures DG having different intervals from each other.

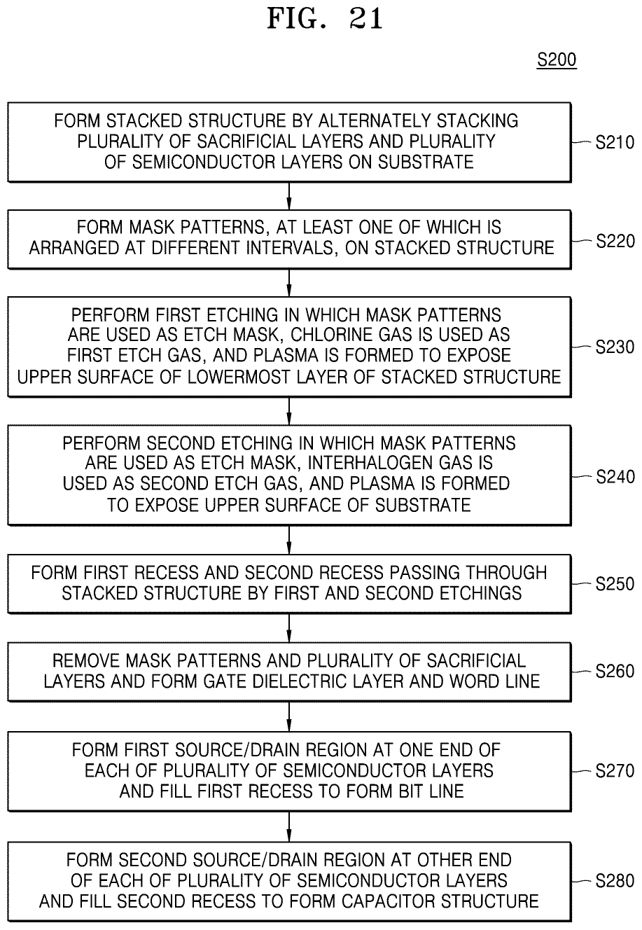

FIG. 21 is a flowchart of a method S200 of manufacturing a semiconductor device, according to another embodiment.

Referring to FIG. 21, the method S200 of manufacturing a semiconductor device, according to the inventive concept, may include first to eighth operations S210 to S280.

The method S200 of manufacturing a semiconductor device, according to the inventive concept, may include the first operation S210 of forming a stacked structure on a substrate by alternately stacking a plurality of sacrificial layers and a plurality of semiconductor layers, the second operation S220 of forming mask patterns, at least one of which is arranged at different intervals with respect to at least some adjacent mask patterns, on the stacked structure, the third operation S230 of performing first etching in which the mask patterns are used as an etch mask, chlorine gas is used as a first etch gas, and plasma is formed to expose an upper surface of the lowermost layer of the stacked structure, the fourth operation S240 of performing second etching in which the mask patterns are used as an etch mask, an interhalogen gas is used as a second etch gas, and plasma is formed to expose the upper surface of the substrate, the fifth operation S250 of forming a first recess and a second recess passing through the stacked structure by the first and second etchings, the sixth operation S260 of removing the mask patterns and the plurality of sacrificial layers and forming a gate dielectric layer and a word line, the seventh operation S270 of forming a first source/drain region at one end of each of the plurality of semiconductor layers and filling the first recess to form a bit line, and the eighth operation S280 of forming a second source/drain region at the other end of each of the plurality of semiconductor layers and filling the second recess to form a capacitor structure.

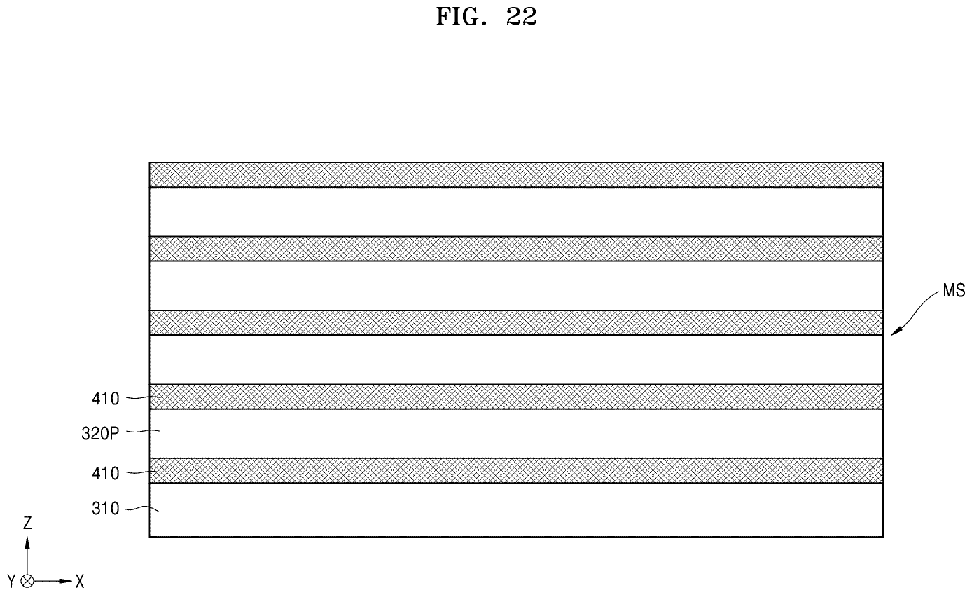

The technical features of the first to eighth operations S210 to S280 are described in detail below with reference to FIGS. 22 to 30.

FIGS. 22 to 30 are cross-sectional views illustrating an example process sequence of the method of manufacturing a semiconductor device in FIG. 21.

Referring to FIG. 22, a stacked structure MS in which a plurality of sacrificial layers 410 and a plurality of semiconductor layers 320P are alternately stacked may be formed on a substrate 310.

The substrate 310 may include a single crystalline semiconductor material. For example, the substrate 310 may include a semiconductor material, such as silicon (Si).

The plurality of sacrificial layers 410 and the plurality of semiconductor layers 320P may each include a semiconductor material. The sacrificial layer 410 may include a semiconductor material having an etch selectivity with respect to the semiconductor layer 320P. In some embodiments, the sacrificial layer 410 may have an etch selectivity with respect to the substrate 310. In some embodiments, the semiconductor layer 320P may include a material having the same or similar etch characteristics as the substrate 310. In some embodiments, the plurality of sacrificial layers 410 may each include silicon germanium, and the plurality of semiconductor layers 320P may each include silicon.

The plurality of sacrificial layers 410 and the plurality of semiconductor layers 320P may be formed by CVD, PECVD, or ALD. In some embodiments, the plurality of sacrificial layers 410 and the plurality of semiconductor layers 320P may each be formed in a single crystalline state by using an underlying layer in contact therewith as a seed layer, or may each be formed in a single crystalline state through a heat treatment process.

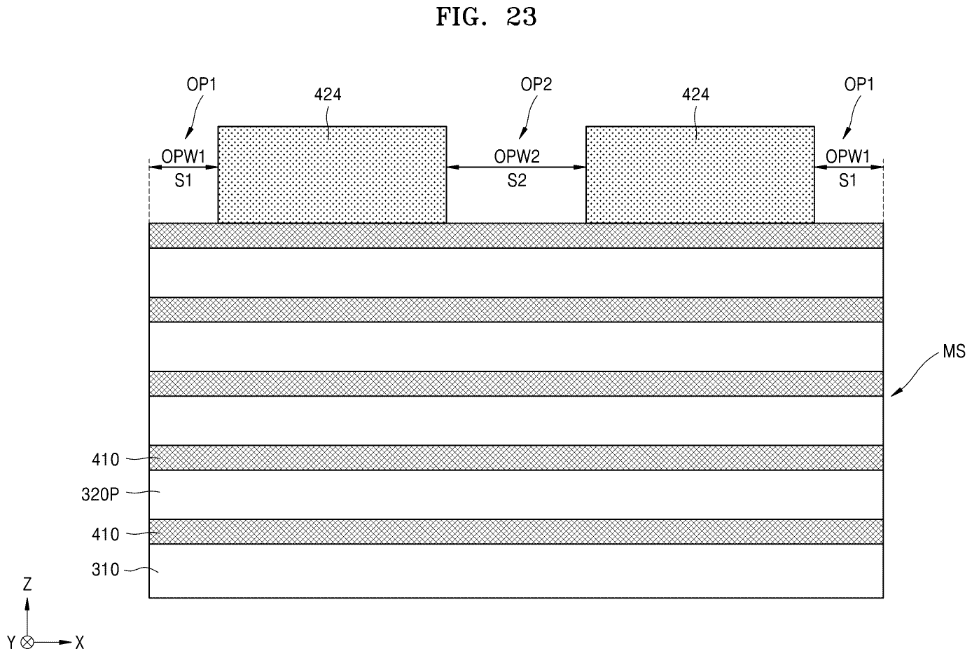

Referring to FIG. 23, mask patterns 424, at least one of which are arranged at different intervals with respect to at least some adjacent mask patterns, may be formed on the stacked structure MS.

The mask patterns 424 may be formed on the stacked structure MS. The mask patterns 424 may have a first opening OP1 and a second opening OP2 for etching the stacked structure MS. The first opening OP1 may have a first opening width OPW1, and the second opening OP2 may have a second opening width OPW2 that is greater than the first opening width OPW1. Accordingly, the mask patterns 424 may be formed to have a first interval S1 and a second interval S2 that is greater than the first interval S1. That is, the mask patterns 424, at least one of which is arranged at different intervals with respect to at least some adjacent mask patterns, may be formed.

The mask patterns 424 may include materials having an etch selectivity with respect to the plurality of sacrificial layers 410 and the plurality of semiconductor layers 320P. In some embodiments, the mask patterns 424 may each include silicon nitride. That is, the mask patterns 424 may be a hard mask.

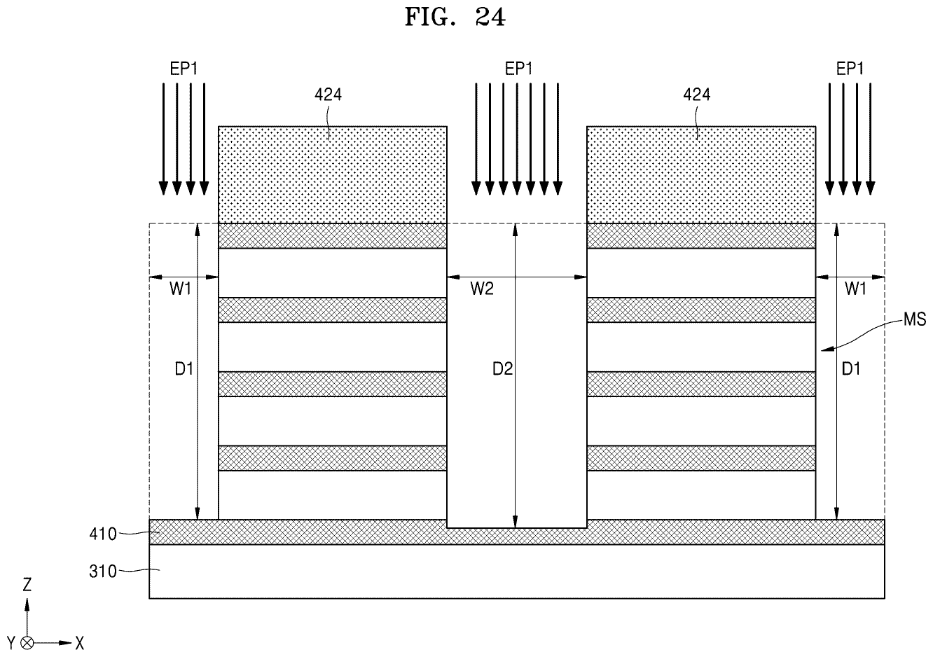

Referring to FIG. 24, a first etching process EP1 may be performed by using the mask patterns 424 as an etch mask.

The first etching process EP1 may be a dry etching process using the plasma etching apparatus 1000 described above.

The first etching process EP1 in which chlorine gas (Cl₂) is used as a first etch gas and first plasma is formed in the process chamber 1100 to expose the upper surface of the lowermost layer (i.e., the sacrificial layer) of the stacked structure MS may be performed on the first opening OP1 and the second opening OP2 of the mask patterns 424.

The chlorine gas (Cl₂) may be used alone as the first etch gas, or the chlorine gas (Cl₂) may be mixed with nitrogen gas (N₂) and the mixed gas may be used as the first etch gas. The nitrogen gas (N₂) may be referred to as a base gas.

Because the second opening width OPW2 of the second opening OP2 is relatively greater than the first opening width OPW1 of the first opening OP1, a recess having a first width W1 and a first depth D1 may be formed in an area corresponding to the first opening OP1 and a recess having a second width W2 and a second depth D2 may be formed in an area corresponding to the second opening OP2.

The first etching process EP1 is an etching process with a low selectivity, and the stacked structure MS may be etched in proportion to an etch time. Specifically, in the first etching process EP1, the etch selectivity of the first etch gas with respect to silicon germanium/silicon may be in a range of about 1 to about 2.

Because the exposed surface of the area corresponding to the second opening OP2 is relatively large, the second depth D2 by the first etching process EP1 may be greater than the first depth D1. Accordingly, a portion of the lowermost layer (i.e., the sacrificial layer) of the stacked structure MS may be overetched in the area corresponding to the second opening OP2. This is for completely removing the layer (i.e., the semiconductor layer) immediately above the lowermost layer (i.e., the sacrificial layer) in the area corresponding to the first opening OP1.

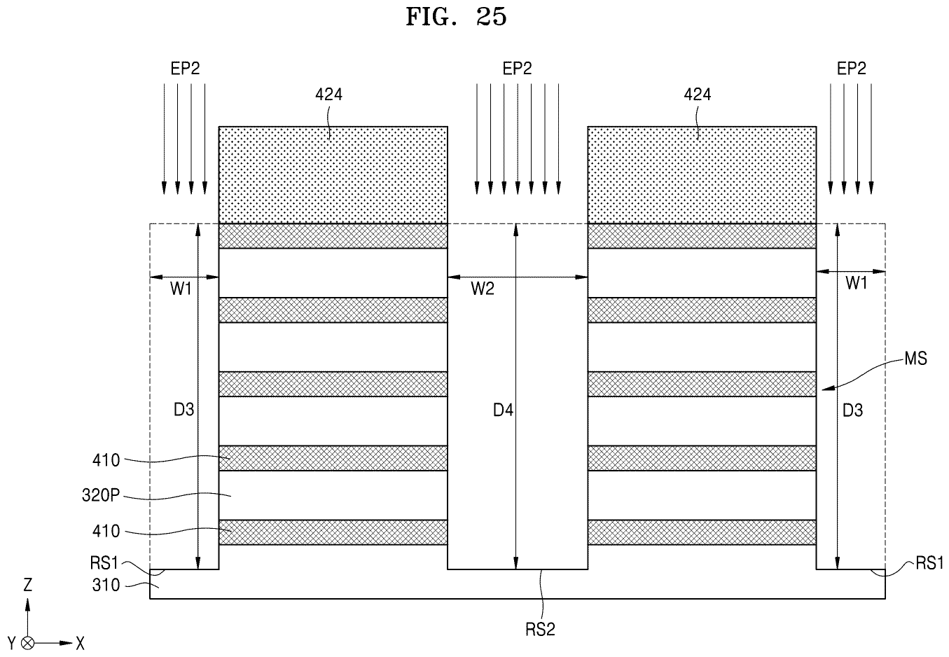

Referring to FIG. 25, a second etching process EP2 may be performed by using the mask patterns 424 as an etch mask.

The second etching process EP2 may be a dry etching process using the plasma etching apparatus 1000 described above.

The second etching process EP2 in which an interhalogen gas is used as a second etch gas and second plasma is formed in the process chamber 1100 to expose the upper surface of the substrate 310 through the stacked structure MS may be performed on the first opening OP1 and the second opening OP2 of the mask patterns 424.

The interhalogen gas may be used alone as the second etch gas, or the interhalogen gas may be mixed with nitrogen gas (N₂), which is a base gas, and the mixed gas may be used as the second etch gas.

The second etch gas may be any one selected from BrF₅, IF₅, and IF₇ gases, and more specifically, the second etch gas may use IF₇ gas.

To perform the second etching process EP2, a process pressure of the process chamber 1100 in the plasma etching apparatus 1000 may be in a range of about 1 m Torr to about 1 Torr, and a process temperature of the process chamber 1100 may be in a range of about 25° C. to about 100° C.

The second opening width OPW2 of the second opening OP2 is relatively greater than the first opening width OPW1 of the first opening OP1, but the second etching process EP2 is an etching process having a high selectivity, and thus, a recess having a first width W1 and a third depth D3 may be formed in an area corresponding to the first opening OP1 and a recess having a second width W2 and a fourth depth D4 may be formed in an area corresponding to the second opening OP2.

The second etching process EP2 is an etching process with a high selectivity, and the stacked structure MS may be etched according to an etch material. Specifically, in the second etching process EP2, the etch selectivity of the second etch gas with respect to silicon germanium/silicon may be in a range of about 10 to about 40.

Therefore, regardless of the sizes of the exposed surfaces of the areas corresponding to the first opening OP1 and the second opening OP2, the third depth D3 and the fourth depth D4 by the second etching process EP2 may be substantially equal to each other. To completely remove the lowermost layer (i.e., the sacrificial layer) of the stacked structure MS, a portion of the substrate 310 may be overetched.

Accordingly, a first recess RS1 and a second recess RS2 that pass through the stacked structure MS and expose the substrate 310 may be formed. Each of the first recess RS1 and the second recess RS2 may have a shape extending along a second horizontal direction Y.

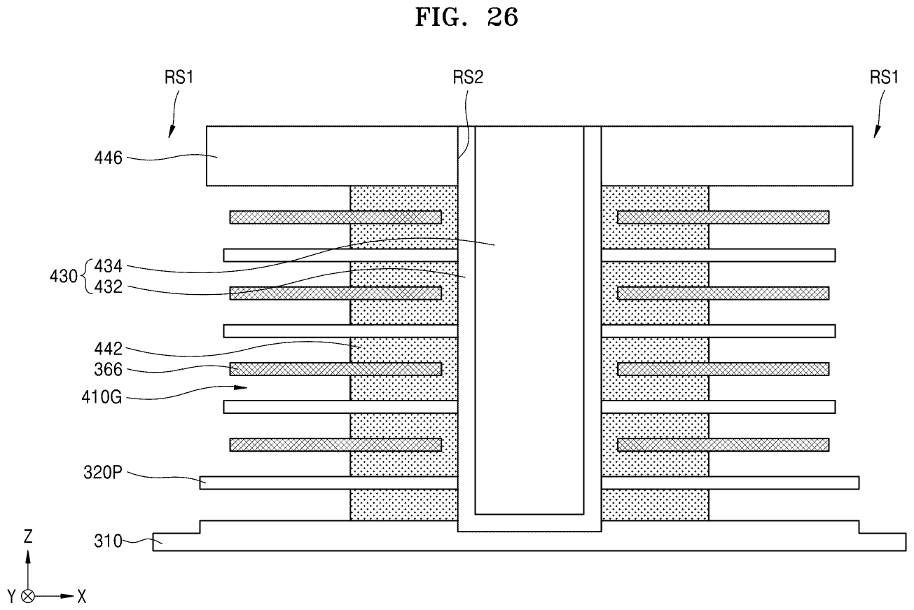

Referring to FIG. 26, a filling structure 430 that fills the second recess RS2 may be formed, and then, the mask patterns 424 may be removed.

In some embodiments, the filling structure 430 may include a liner layer 432 and a filling layer 434. The liner layer 432 may conformally cover the bottom surface and the side surface of the second recess RS2. The filling layer 434 may cover the liner layer 432 and fill the second recess RS2. In some embodiments, the liner layer 432 may include silicon nitride.

In some embodiments, a portion of the plurality of semiconductor layers 320P may be removed through an isotropic etching process having an etch selectivity with respect to the liner layer 432, and thus, the horizontal width and the vertical thickness of the plurality of semiconductor layers 320P may be further reduced.

Next, a plurality of support dielectric layers 442 covering the surfaces of the plurality of semiconductor layers 320P and a plurality of separation dielectric layers 366 covering the surfaces of the plurality of support dielectric layers 442 may be formed.

An upper dielectric layer 446 may be formed on the top support dielectric layer 442. The upper dielectric layer 446 may include silicon oxide and may be arranged at the same level as the upper surface of the filling structure 430.

By removing a portion of the plurality of support dielectric layers 442, a portion of the separation dielectric layers 366 and a portion of the plurality of semiconductor layers 320P may be arranged to protrude outward from the support dielectric layer 442.

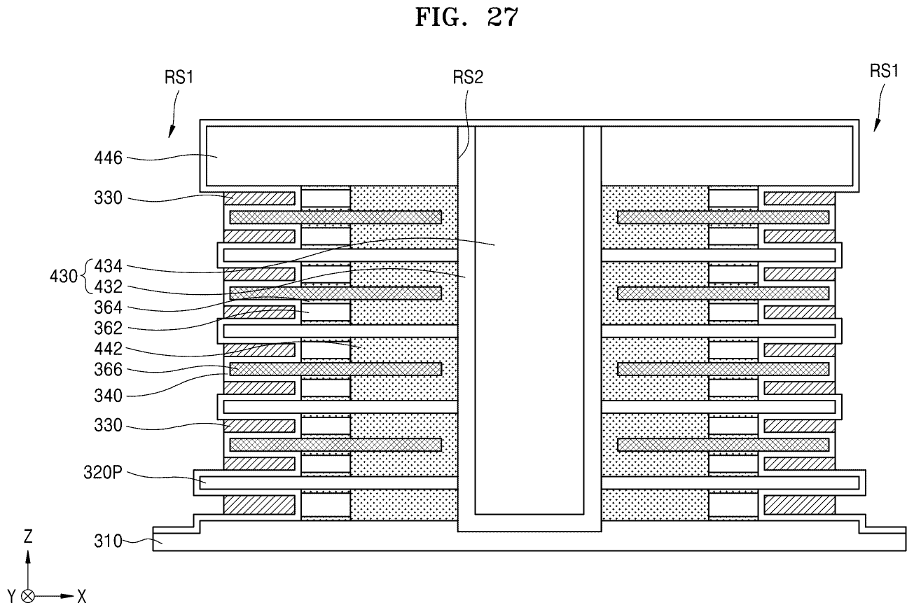

Referring to FIG. 27, a spacer liner layer 364 covering an inner surface of a portion of a space between the plurality of semiconductor layers 320P and the plurality of separation dielectric layers 366 and a spacer filling layer 362 filling a portion of the space may be formed.

After the spacer liner layer 364 and the spacer filling layer 362 are formed, a gate dielectric layer 340 and a word line 330 covering the exposed surface thereof may be formed. The word line 330 may be formed by forming a gate electrode material layer that covers the gate dielectric layer 340 and fills the first recess RS1 and then removing a portion of the gate electrode material layer so that the remaining portion of the gate electrode material layer remains only in a portion inside the remaining portion of the space between the plurality of semiconductor layers 320P and the plurality of separation dielectric layers 366.

The gate dielectric layer 340 may include at least one selected from silicon oxide, a high-k dielectric material having a higher dielectric constant than silicon oxide, and a ferroelectric material.

In some embodiments, the word line 330 may include a conductive barrier layer covering the gate dielectric layer 340 and a conductive filling layer covering the conductive barrier layer. The conductive barrier layer may include, for example, a metal, a conductive metal nitride, a conductive metal silicide, or any combination thereof.

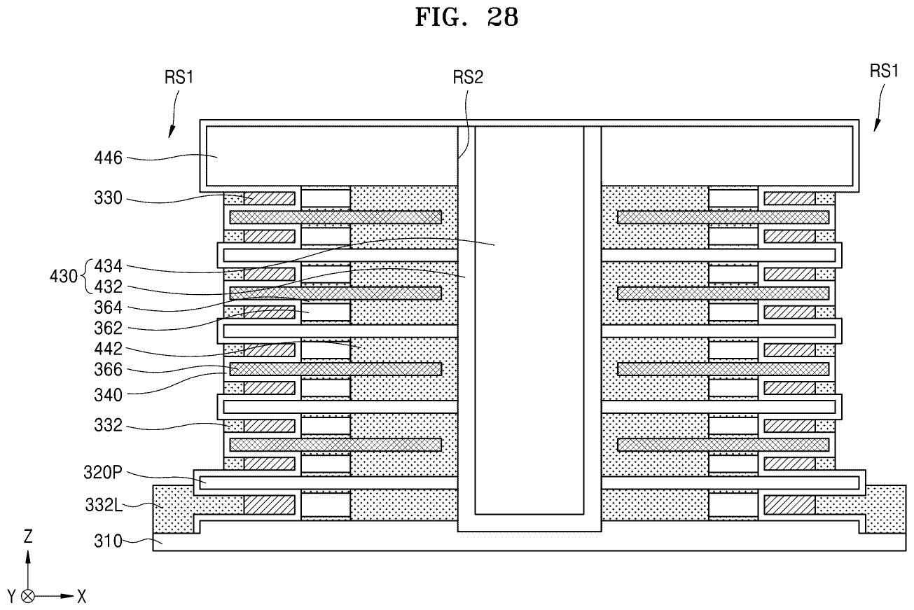

Referring to FIG. 28, a plurality of spacers 332 may be formed to fill the space between the plurality of semiconductor layers 320P and the plurality of separation dielectric layers 366 in the vertical direction Z.

In some embodiments, the plurality of spacers 332 may each include silicon nitride. In some embodiments, some of the plurality of spacers 332 may cover the surface of the substrate 310 that is exposed to the bottom surface of the first recess RS1. On the other hand, a portion arranged on the substrate 310 among the plurality of spacers 332 is referred to as a bottom spacer layer 332L and may have a relatively great thickness.

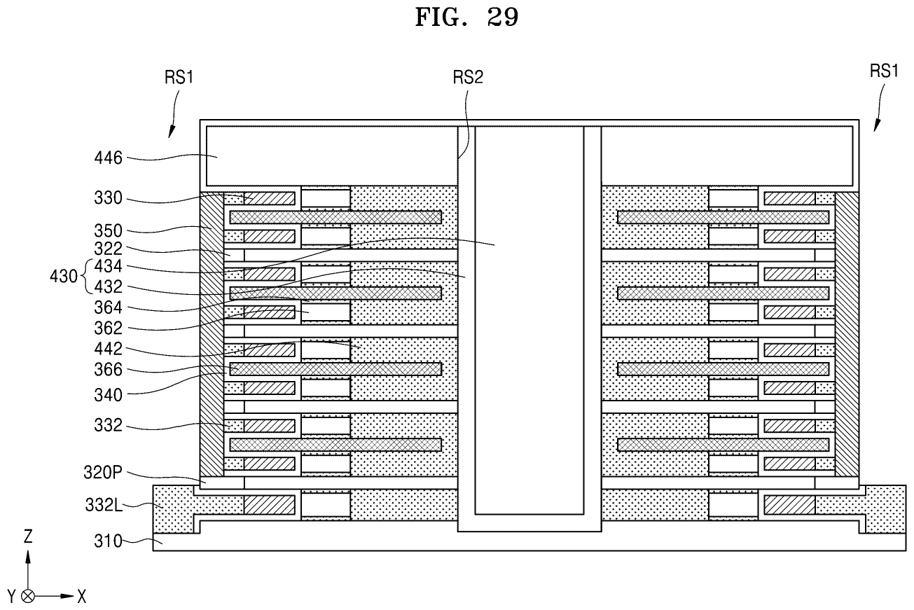

Referring to FIG. 29, a portion of the plurality of semiconductor layers 320P exposed through the first recess RS1 and a portion of the gate dielectric layer 340 covering the same may be removed to expose one end of each of the plurality of semiconductor layers 320P facing the first recess RS1.

In some embodiments, a plurality of first source/drain regions 322 may be formed by implanting impurities into one end of each of the plurality of semiconductor layers 320P exposed through the first recess RS1.

Next, a plurality of bit lines 350 that are in contact with the plurality of first source/drain regions 322 and extend in the vertical direction Z in the plurality of first recesses RS1 may be formed.

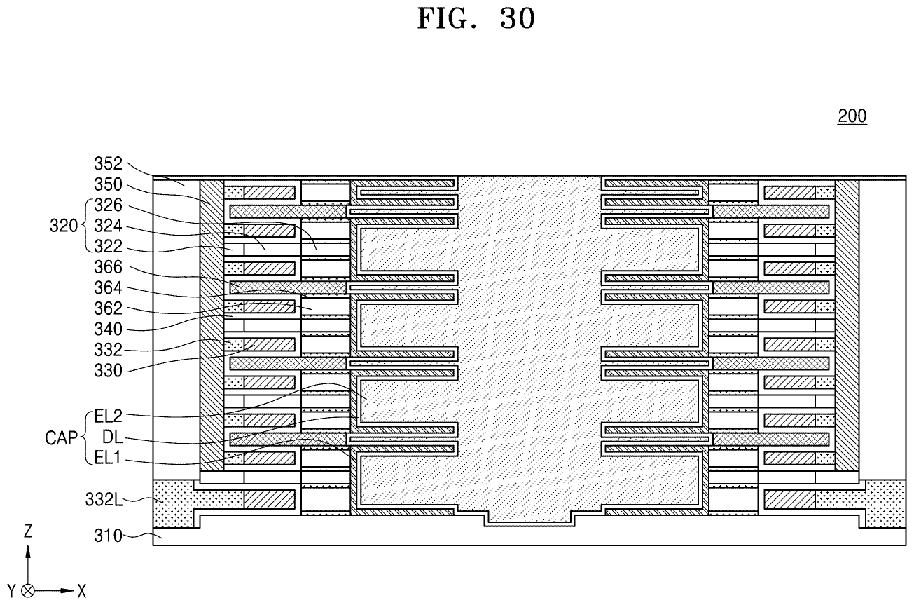

Referring to FIG. 30, a bit line dielectric layer 352 that fills the first recess RS1 may be formed, and a filling structure 430 that fills the second recess RS2 may be removed.

In some embodiments, the bit line dielectric layer 352 may include silicon oxide. After the filling structure 430 that fills the second recess RS2 is removed, a removal space (not shown) that communicates with the second recess RS2 may be formed by removing the plurality of support dielectric layers 442 through the second recess RS2.

In some embodiments, a plurality of second source/drain regions 326 may be formed by implanting impurities into one end of each of the plurality of semiconductor layers 320P exposed through the second recess RS2. Accordingly, the plurality of semiconductor layers 320P may include a first source/drain region 322, a channel layer 324, and a second source/drain region 326, which may become a plurality of transistor bodies 320 and may be sequentially arranged in this stated order along the first horizontal direction X.

Next, a first electrode EL1 may be conformally formed in a portion of the removal space defined by the plurality of separation dielectric layers 366.

Next, a capacitor dielectric layer DL may be conformally formed on the first electrode EL1 in the removal space, and a second electrode EL2 may be formed on the capacitor dielectric layer DL to fill the removal space. For example, the first source/drain region 322 may be connected to the bit line 350 and the second source/drain region 326 may be connected to the first electrode EL1 of a cell capacitor CAP.

A semiconductor device 200 according to the inventive concept, which is formed by the manufacturing process described above, may have a vertical dynamic random access memory (DRAM) structure having a three-dimensional structure, in which each of the plurality of semiconductor layers 320P operates as a channel region.

Ultimately, the method S200 of manufacturing a semiconductor device, according to the inventive concept, has an effect of improving productivity and cost reduction according to precise etching of the thin-film by etching a desired thin-film in an accurate pattern through a plasma etching process using an etch gas with a high selectivity in the mask patterns 424 having different intervals from each other.

While the inventive concept has been particularly shown and described with reference to embodiments thereof, it will be understood that various changes in form and details may be made therein without departing from the spirit and scope of the following claims.

What is claimed is:

1. A selective thin-film etching method comprising:
forming a stacked structure on a substrate by alternately stacking a plurality of silicon germanium layers and a plurality of silicon layers;
forming mask patterns, at least one of which is disposed at different intervals with respect to at least some adjacent patterns, on the stacked structure;
performing first etching, in which the mask patterns are used as an etch mask, chlorine gas is used as a first etch gas, and first plasma is formed in a process chamber, to expose an upper surface of a lowermost layer of the stacked structure;
performing second etching, in which the mask patterns are used as an etch mask, an interhalogen gas is used as a second etch gas, and second plasma is formed in the process chamber, to expose an upper surface of the substrate; and
removing the mask patterns.

2. The selective thin-film etching method of claim 1, wherein the second etch gas is a gas selected from the group consisting of BrF₅, IF₅, and IF₇ gases.

3. The selective thin-film etching method of claim 2, wherein the second etch gas is the IF₇ gas.

4. The selective thin-film etching method of claim 1, wherein
a process pressure of the process chamber is in a range of 1 m Torr to 1 Torr, and
a process temperature of the process chamber is in a range of 25° C. to 100° C.

5. The selective thin-film etching method of claim 1, wherein
the substrate comprises silicon, and
an etch selectivity of the second etch gas with respect to silicon germanium/silicon is 10 to 40.

6. The selective thin-film etching method of claim 5, wherein
the mask patterns each comprise silicon nitride, and
an etch selectivity of the second etch gas with respect to silicon germanium/silicon nitride is 20 to 60.

7. The selective thin-film etching method of claim 6, wherein, in the first etching, the etch selectivity of the first etch gas with respect to the silicon germanium/silicon is 1 to 2.

8. The selective thin-film etching method of claim 1, wherein
in the first etching, the first etch gas is used alone or mixed with a base gas, and
in the second etching, the second etch gas is used alone or mixed with a base gas.

9. The selective thin-film etching method of claim 8, wherein the base gas comprises nitrogen gas.

10. The selective thin-film etching method of claim 1, wherein the second plasma is inductively coupled plasma or capacitively coupled plasma.

11. A method of manufacturing a semiconductor device, the method comprising:
forming a stacked structure on a substrate by alternately stacking a plurality of sacrificial layers and a plurality of nanosheet layers;
forming dummy gate structures, at least one of which is disposed at different intervals with respect to at least some adjacent dummy gate structures, on the stacked structure;
performing first etching, in which the dummy gate structures are used as an etch mask, chlorine gas is used as a first etch gas, and first plasma is formed in a process chamber, to expose an upper surface of a lowermost layer of the stacked structure;
performing second etching, in which the dummy gate structures are used as an etch mask, an interhalogen gas is used as a second etch gas, and second plasma is formed in the process chamber, to expose an upper surface of the substrate;
separating the plurality of nanosheet layers into a plurality of nanosheets by forming recesses passing through the stacked structure by the first and second etchings;
forming source/drain regions in the recesses;
forming a gate space by removing the plurality of sacrificial layers and the dummy gate structures; and
forming a gate dielectric layer and a gate electrode to fill the gate space.

12. The method of claim 11, wherein the second etch gas is IF₇ gas.

13. The method of claim 11, wherein each of the plurality of sacrificial layers comprises a silicon germanium thin-film,
each of the plurality of nanosheet layers comprises a silicon thin-film,
the substrate comprises silicon, and
each of the dummy gate structures comprises silicon nitride.

14. The method of claim 13, wherein
an etch selectivity of the second etch gas with respect to silicon germanium/silicon is 10 to 40, and
an etch selectivity of the second etch gas with respect to silicon germanium/silicon nitride is 20 to 60.

15. The method of claim 11, wherein the gate electrode has a gate-all-around structure surrounding the plurality of nanosheets.

16. A method of manufacturing a semiconductor device, the method comprising:
forming a stacked structure on a substrate by alternately stacking a plurality of sacrificial layers and a plurality of semiconductor layers;
forming mask patterns, at least one of which is disposed at different intervals with respect to at least some adjacent mask patterns, on the stacked structure;
performing first etching, in which the mask patterns are used as an etch mask, chlorine gas is used as a first etch gas, and first plasma is formed in a process chamber, to expose an upper surface of a lowermost layer of the stacked structure;
performing second etching in which the mask patterns are used as an etch mask, an interhalogen gas is used as a second etch gas, and second plasma is formed in the process chamber, to expose an upper surface of the substrate;
forming a first recess and a second recess passing through the stacked structure by the first and second etchings;
removing the mask patterns and the plurality of sacrificial layers and forming a gate dielectric layer and a word line;
forming a first source/drain region at one end of each of the plurality of semiconductor layers and filling the first recess to form a bit line; and
forming a second source/drain region at another end of each of the plurality of semiconductor layers and filling the second recess to form a capacitor structure.

17. The method of claim 16, wherein the second etch gas is IF₇ gas.

18. The method of claim 16, wherein
each of the plurality of sacrificial layers comprises a silicon germanium thin-film,
each of the plurality of semiconductor layers comprises a silicon thin-film,
the substrate comprises silicon, and
each of the mask patterns comprises silicon nitride.

19. The method of claim 18, wherein
an etch selectivity of the second etch gas with respect to silicon germanium/silicon is 10 to 40, and
an etch selectivity of the second etch gas with respect to silicon germanium/silicon nitride is 20 to 60.

20. The method of claim 16, wherein each of the plurality of semiconductor layers operates as a channel region to constitute a vertical dynamic random access memory (DRAM) having a three-dimensional structure.
